(19) United States
(12) Patent Application Publication
(10) Pub. No.: US 2017/0134049 A1
(43) Pub. Date: May 11, 2017

(54) DECODING METHOD, MEMORY STORAGE DEVICE AND MEMORY CONTROL CIRCUIT UNIT

(71) Applicant: EpoStar Electronics Corp., Miaoli (TW)

(72) Inventors: Yu-Hua Hsiao, Hsinchu County (TW); Hung-Chi Chang, Hsinchu City (TW); Heng-Lin Yen, Hsinchu County (TW)

(21) Appl. No.: 14/981,965

(22) Filed: Dec. 29, 2015

(30) Foreign Application Priority Data
Nov. 5, 2015 (TW) 104136484

(51) Int. Cl. H03M 13/11; H03M 13/00; G06F 11/10; G11C 16/08

(52) U.S. Cl. CPC H03M 13/1174; G11C 16/08; H03M 13/6566; G06F 11/1008

(57) ABSTRACT

A decoding method, a memory storage device and a memory control circuit unit are provided. The method includes: determining an offset threshold value and a corresponding check matrix; receiving response data from a rewritable non-volatile memory module and performing an iterative decoding process. The check matrix includes at least one sub-matrix group, each sub-matrix of the sub-matrix group has a default dimension, and the offset threshold value is less than a default dimension value corresponding to the default dimension In the iterative decoding process, several default groups in a data set are shifted, so as to obtain first shift groups, while an offset of each first shift group with respect to a corresponding group among the default groups is not over the default threshold value. Therefore, decoding reference data used in the iterative decoding process may be generated more efficiently.

### CROSS-REFERENCE TO RELATED APPLICATION

This application claims the priority benefit of Taiwan application serial no. 104136484, filed on Nov. 5, 2015. The entirety of the above-mentioned patent application is hereby incorporated by reference herein and made a part of this specification.

### BACKGROUND

1. Technology Field

The disclosure is directed to a decoding technique and more particularly, to a decoding method, a memory storage device and a memory control circuit unit.

2. Description of Related Art

Along with the widespread of digital cameras, cell phones, and MP3 players in recently years, the consumers' demand to storage media has increased drastically. Because a rewritable non-volatile memory (e.g., a flash memory) is capable of providing features such as data non-volatility, low power consumption, small volume, and non-mechanical structure, the rewritable non-volatile memory is adapted to be built in various portable multi-media apparatuses.

Generally speaking, in order to avoid data read from a memory apparatus from encountering errors, data to be stored in the memory apparatus is encoded before being stored. When the data is to be read, the entire encoded data is read from the memory apparatus and be decoded. Thereby, errors that may be probably exist therein may be corrected through a decoding procedure. In an ordinary decoding circuit, operations of matrix addition can be used in replacement with operations of matrix multiplication to improve a decoding speed; however, for achieving a decoding operation complying with a specific standard, the number of the selectors/shift registers configured in the decoding circuit cannot be easily adjusted.

Nothing herein should be construed as an admission of knowledge in the prior art of any portion of the disclosure. Furthermore, citation or identification of any document in this application is not an admission that such document is available as prior art to the disclosure, or that any reference forms a part of the common general knowledge in the art.

### SUMMARY

The disclosure is directed to a decoding method, a memory storage device and a memory control circuit unit capable of achieving reduction in the number of required selectors/shift registers through the operations of matrix addition.

According to an exemplary embodiment of the disclosure, a decoding method for a rewritable non-volatile memory module is provided. The decoding method includes: determining an offset threshold value and a check matrix corresponding to the offset threshold value, wherein the check matrix includes at least one sub-matrix group, each sub-matrix of the at least one sub-matrix group has a default dimension, the offset threshold value is less than a default dimension value corresponding to the default dimension, and the at least one sub-matrix group includes a first sub-matrix group; transmitting a read command sequence, wherein the read command sequence instructs to read a physical unit of the rewritable non-volatile memory module; receiving response data corresponding to the read command sequence; and performing an iterative decoding process on the response data. The iterative decoding process includes: generating a data set corresponding to the response data, wherein the data set includes a plurality of default groups; shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and generating a decoding reference data according to the first shift groups.

According to another exemplary embodiment of the disclosure, a memory storage device including a connection interface unit, a rewritable non-volatile memory module and a memory control circuit unit is provided. The connection interface unit is configured to couple to a host system. The memory control circuit unit is coupled to the connection interface unit and the rewritable non-volatile memory module. The memory control circuit unit is configured to determine an offset threshold value and a check matrix corresponding to the offset threshold value. The check matrix includes at least one sub-matrix group, each sub-matrix of the at least one sub-matrix group has a default dimension, the offset threshold value is less than a default dimension value corresponding to the default dimension, and the at least one sub-matrix group includes a first sub-matrix group. The memory control circuit unit is further configured to transmit a read command sequence, wherein the read command sequence instructs to read a physical unit of the rewritable non-volatile memory module. The memory control circuit unit is further configured to receive response data corresponding to the read command sequence. The memory control circuit unit is further configured to perform an iterative decoding process on the response data. The iterative decoding process includes: generating a data set corresponding to the response data, wherein the data set includes a plurality of default groups; shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and generating a decoding reference data according to the first shift groups.

According to another exemplary embodiment of the disclosure, a memory control circuit unit configured to control a rewritable non-volatile memory module is provided. The memory control circuit unit includes a host interface, a memory interface, an error checking and correcting circuit, and a memory management circuit. The host interface is configured to couple to a host system. The memory interface is configured to couple to the rewritable non-volatile memory module. The memory management circuit is coupled to the host interface, the memory interface, and the error checking and correcting circuit. The memory management circuit is configured to determine an offset threshold value and a check matrix corresponding to the offset threshold value. The check matrix includes at least one sub-matrix group, each sub-matrix of the at least one sub-matrix group has a default dimension, the offset threshold value is less than a default dimension value corresponding to the default dimension, and the at least one sub-matrix group includes a first sub-matrix group. The memory management circuit is further configured to transmit a read command sequence, wherein the read command sequence instructs to read a physical unit of the rewritable non-volatile memory module. The memory management circuit is further configured to receive response data corresponding to the read command sequence. The error checking and correcting circuit is configured to perform an iterative decoding process on the response data. The iterative decoding process includes: generating a data set corresponding to the response data, wherein the data set includes a plurality of default groups; shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and generating a decoding reference data according to the first shift groups.

To sum up, after the offset threshold value and its corresponding check matrix are determined, in the iterative decoding process, the groups in a data set are shifted correspondingly to the check matrix, and each of the corresponding offsets is limited to not over the set offset threshold value. Thereby, in an exemplary embodiment of the disclosure, the number of the selectors/shift registers configured in the error checking and correcting circuit can be reduced. Moreover, in an exemplary embodiment of the disclosure, the generation of the decoding reference data according to the shift groups can also contribute to improving execution efficiency of certain stages in the iterative decoding process.

It should be understood, however, that this Summary may not contain all of the aspects and embodiments of the disclosure, is not meant to be limiting or restrictive in any manner, and that the disclosure as disclosed herein is and will be understood by those of ordinary skill in the art to encompass obvious improvements and modifications thereto.

In order to make the aforementioned and other features and advantages of the disclosure more comprehensible, several embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a host system, a memory storage device and an input/output (I/O) device according to an exemplary embodiment of the disclosure.

FIG. 2 is a schematic diagram illustrating a host system, a memory storage device and an I/O device according to another exemplary embodiment the disclosure.

FIG. 3 is a schematic diagram illustrating a host system and a memory storage device according to another exemplary embodiment the disclosure.

FIG. 4 is a schematic block diagram illustrating the memory storage device according to an exemplary embodiment the disclosure.

FIG. 5 is a schematic block diagram illustrating the memory control circuit unit according to an exemplary embodiment of the disclosure.

FIG. 6 is a schematic diagram illustrating belief propagation of a low density parity code (LDPC) algorithm according to an exemplary embodiment of the disclosure.

FIG. 7 is a schematic diagram illustrating a parity check matrix according to an exemplary embodiment of the disclosure.

FIG. 8 is a schematic diagram illustrating a parity check procedure according to an exemplary embodiment of the disclosure.

FIG. 9 is a schematic diagram of obtaining a syndrome set corresponding to the parity check procedure according to an exemplary embodiment of the disclosure.

FIG. 10 and FIG. 11 are schematic diagrams of obtaining a syndrome set corresponding to the bit-flipping algorithm according to another exemplary embodiment of the disclosure.

FIG. 12 and FIG. 13 are schematic diagrams of obtaining a minimum value set corresponding to a min-sum algorithm according to another exemplary embodiment of the disclosure.

FIG. 14 is a schematic diagram of the group shifting according to an exemplary embodiment of the disclosure.

FIG. 15A and FIG. 15B are schematic diagrams illustrating a stage shifter structure according to an exemplary embodiment of the disclosure.

FIG. 16A and FIG. 16B are schematic diagrams illustrating a barrel shifter structure according to an exemplary embodiment of the disclosure.

FIG. 17 is a schematic diagram illustrating a reduced shifter structure according to another exemplary embodiment of the disclosure.

FIG. 18 is a flowchart illustrating a decoding method according to an exemplary embodiment of the disclosure.

FIG. 19 is a schematic block diagram illustrating the error checking and correcting circuit according to an exemplary embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Embodiments of the disclosure may comprise any one or more of the novel features described herein, including in the Detailed Description, and/or shown in the drawings. As used herein, “at least one”, “one or more”, and “and/or” are open-ended expressions that are both conjunctive and disjunctive in operation. For example, each of the expressions “at least on of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”), “one or more” and “at least one” can be used interchangeably herein.

Generally, a memory storage device (also known as a memory storage system) includes a rewritable non-volatile memory module and a controller (also known as a control circuit). The memory storage device is usually configured together with a host system so that the host system may write data to or read data from the memory storage device.

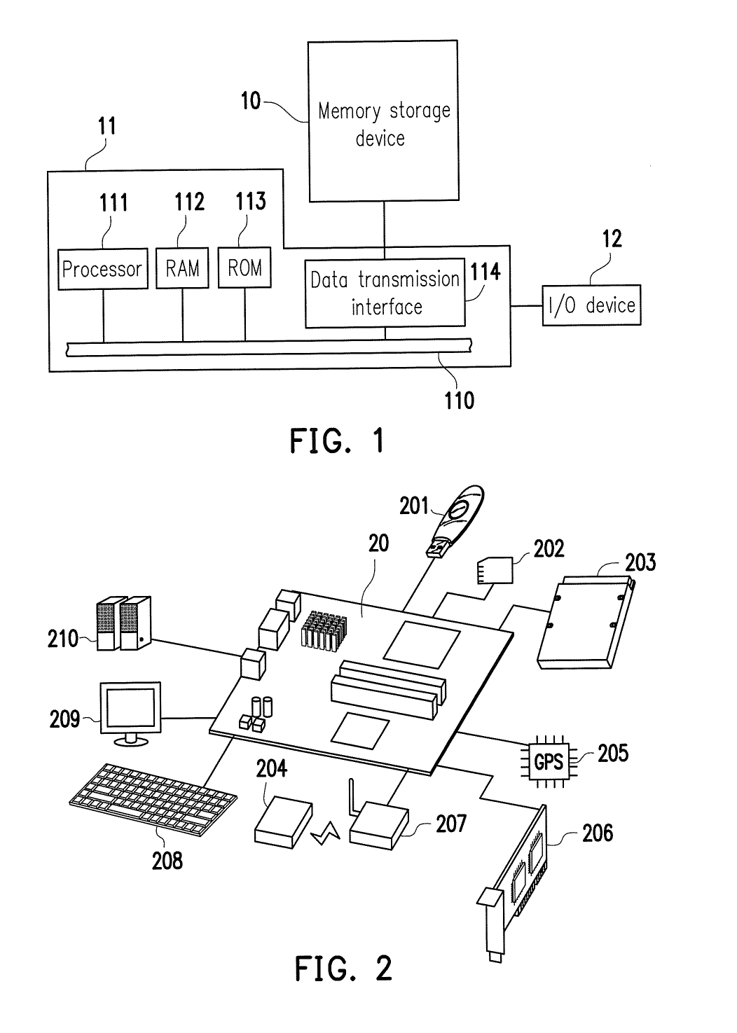

FIG. 1 is a schematic diagram illustrating a host system, a memory storage device and an input/output (I/O) device according to an exemplary embodiment of the disclosure. FIG. 2 is a schematic diagram illustrating a host system, a memory storage device and an I/O device according to another exemplary embodiment the disclosure.

Referring to FIG. 1 and FIG. 2, a host system 11 generally includes a processor 111, a random access memory (RAM) 112, a read only memory (ROM) 113 and a data transmission interface 114. The processor 111, the RAM 112, the ROM 113 and the data transmission interface 114 are coupled to a system bus 110.

In the present exemplary embodiment, the host system 11 is coupled to the memory storage device 10 through the data transmission interface 114. For example, the host system 11 may store data in or read data from the memory storage device 10 through the data transmission interface 114. Additionally, the host system 11 is coupled to the I/O device 12 through the system bus 110. For example, the host system 11 may transmit a signal to or receive a signal from the I/O device 12 through the system bus 110.

In the present exemplary embodiment, the processor 111, the RAM 112, the ROM 113 and the data transmission interface 114 are configured on a motherboard 20 of the host system 11. The number of the data transmission interface 114 may be one or plural. The motherboard 20 is coupled with the memory storage device 10 in a wired or a wireless manner through the data transmission interface 114. The memory storage device 10 is, for example, a flash drive 201, a memory card 202, a solid state drive (SSD) 203 or a wireless memory storage device 204. The wireless memory storage device 204 may be a memory storage device employing various wireless communication techniques, such as a near field communication (NFC) memory storage apparatus, a wireless fidelity (Wi-Fi) memory storage apparatus, a Bluetooth memory storage apparatus or a Bluetooth memory storage apparatus (e.g., an iBeacon) with low power consumption and so on. Additionally, the motherboard 20 may also be coupled to a variety of I/O devices, such as a global positioning system (GPS) module 205, a network interface card 206, a wireless transmission device 207, a keyboard 208, a display 209, and a speaker 210 through the system bus 110. For example, in an exemplary embodiment, the motherboard 20 may access the wireless memory storage device 204 through the wireless transmission device 207.

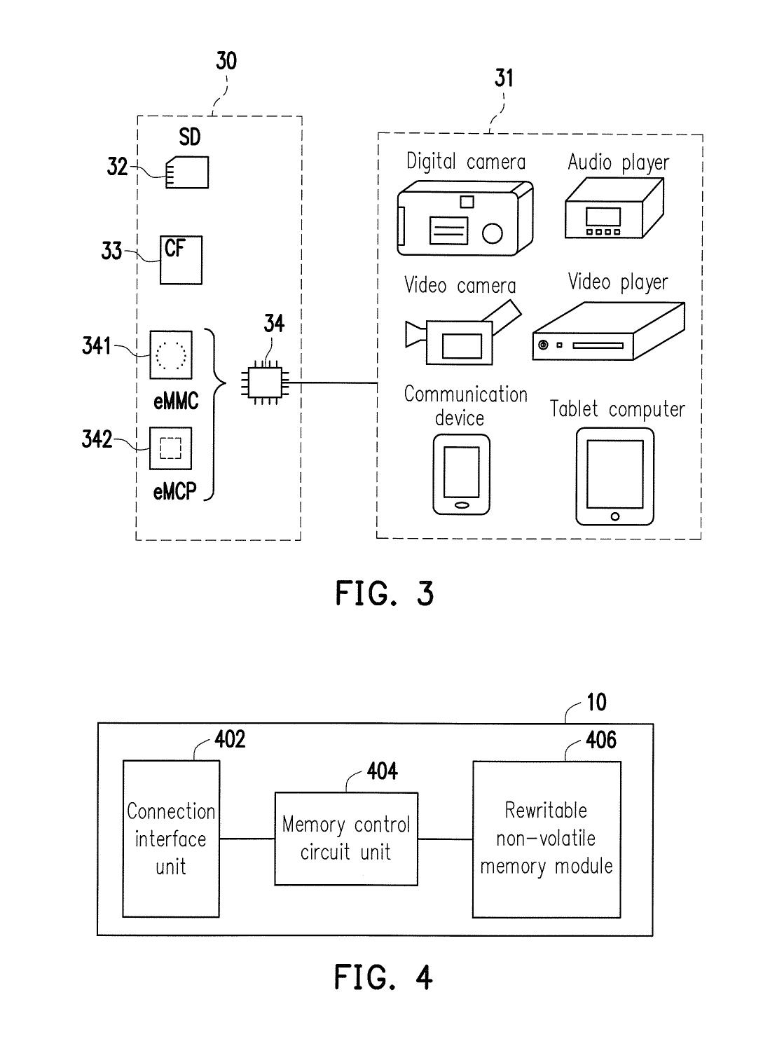

In an exemplary embodiment, the aforementioned host system may substantially be any system used together with the memory storage device for storing data. Even though the host system is described as a computer system in the above exemplary embodiment, however, FIG. 3 is a schematic diagram illustrating a host system and a memory storage device according to another exemplary embodiment the disclosure. Referring to FIG. 3, in another exemplary embodiment, a host system 31 may also be a system, such as a digital camera, a video camera, a communication device, an audio player, a video player, a tablet computer and so on, while a memory storage device 30 may be a non-volatile memory used thereby, such as an secure digital (SD) card 32, a compact flash (CF) card 33 or an embedded storage device 34. The embedded storage device 34 includes an embedded storage device of any kind, where a memory module of any kind is directly coupled to a substrate of the host system, such as an embedded multimedia card (eMMC) 341 and/or an embedded multi-chip package (eMCP) storage device 342.

FIG. 4 is a schematic block diagram illustrating the memory storage device according to an exemplary embodiment the disclosure.

Referring to FIG. 4, the memory storage device 10 includes a connection interface unit 402, a memory control circuit unit 404 and a rewritable non-volatile memory module 406.

In the present exemplary embodiment, the connection interface unit 402 complies with the serial advanced technology attachment (SATA) standard. However, the disclosure is not limited thereto, and the connection interface unit 402 may also comply with the parallel advanced technology attachment (PATA) standard, the Institute of Electrical and Electronic Engineers (IEEE) 1394 standard, the peripheral component interconnect (PCI) express standard, the universal serial bus (USB) standard, the SD interface standard, the ultra high speed-I(UHS-I) standard, the ultra high speed-II (UHS-II) standard, the memory sick (MS) standard, the multi-chip package interface standard, the multi media card (MMC) standard, the eMMC interface standard, the universal flash storage (UFS) interface standard, the eMCP interface standard, the CF interface standard, the integrated device electronics (IDE) standard, or other suitable standards. The connection interface unit 402 may be packaged with the memory control circuit unit 404 in a chip, or disposed outside of a chip including the memory control circuit unit 404.

The memory control circuit unit 404 is configured for executing a plurality of logic gates or control commands which are implemented in a hardware form or in a firmware form and perform operations such as data writing, reading or erasing in the rewritable non-volatile memory module 406 according to commands of the host system 11.

The rewritable non-volatile memory module 406 is coupled to the memory control circuit unit 404 and configured to store data written by the host system 11. The rewritable non-volatile memory module 406 is a single level cell (SLC) NAND flash memory module (i.e., a flash memory module in which a memory cell may store data of 1 bit), a multi level cell (MLC) NAND flash memory module (i.e., a flash memory module in which a memory cell may store data of 2 bits), a triple level cell (TLC) NAND flash memory module (i.e., a flash memory module in which a memory cell may store data of 3 bits), other flash memory modules or other memory modules with the same characteristics.

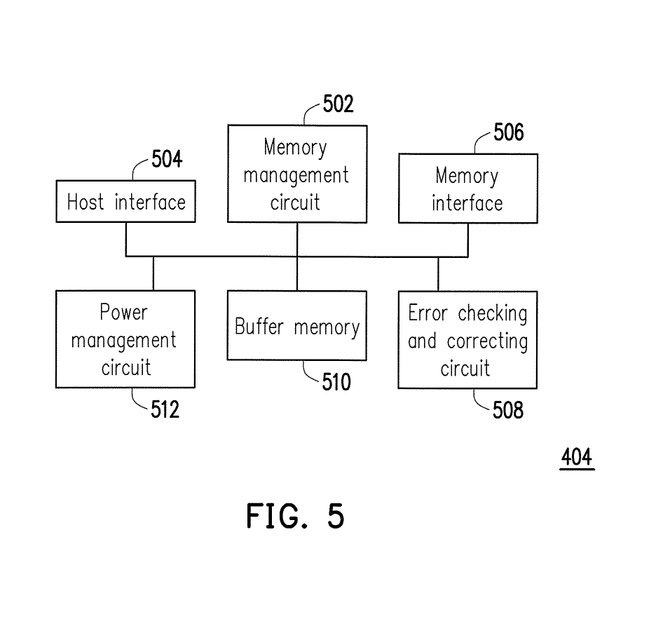

FIG. 5 is a schematic block diagram illustrating the memory control circuit unit according to an exemplary embodiment of the disclosure.

Referring to FIG. 5, the memory control circuit unit 404 includes a memory management circuit 502, a host interface 504, a memory interface 506 and an error checking and correcting circuit 508.

The memory management circuit 502 is configured to control the overall operation of the memory control circuit unit 404. Particularly, the memory management circuit 502 has a plurality of control instructions, and when the memory storage device 10 is operated, the control instructions are executed to perform operations such as, data writing, data reading and data erasing. The operation of the memory management circuit 502 will be described below, which is equivalent to the operation of the memory control circuit unit 404.

In the present exemplary embodiment, the control instructions of the memory management circuit 502 are implemented in a form of firmware. For example, the memory management circuit 502 includes a microprocessor unit (not shown) and a read-only memory (ROM, not shown), where the control instructions are burned into the ROM. When the memory storage device 10 is operated, the control instructions are executed by the microprocessor unit to perform a data writing operation, a data reading operation, a data erasing operation, and so on.

In another exemplary embodiment, the control instructions of the memory management circuit 502 may also be stored in a specific area (for example, a system area in a memory module exclusively used for storing system data) of the rewritable non-volatile memory module 406 in a form of program codes. For example, the memory management circuit 502 includes a microprocessor unit (not shown), a read-only memory (ROM, not shown) and a random access memory (RAM, not shown). In particular, the ROM has a boot code, and when the memory control circuit unit 104 is enabled, the microprocessor unit first executes the boot code to load control instructions from the rewritable non-volatile memory module 406 into the RAM of the memory management circuit 502. Afterwards, the microprocessor unit executes the control instructions to perform a data writing operation, a data reading operation, a data erasing operation, and so on.

Furthermore, in another exemplary embodiment, the control instructions of the memory management circuit 502 may also be implemented in a form of hardware. For example, the memory management circuit 502 may include a micro controller, a memory cell management circuit, a memory writing circuit, a memory reading circuit, a memory erasing circuit and a data processing circuit. The memory cell management circuit, the memory writing circuit, the memory reading circuit, the memory erasing circuit and the data processing circuit are coupled to the micro controller. The memory cell management circuit is configured to manage physical units of the rewritable non-volatile memory module 406; the memory writing circuit is configured to issue a write command sequence to the rewritable non-volatile memory module 406 to write data into the rewritable non-volatile memory module 406; the memory reading circuit is configured to issue a read command sequence to the rewritable non-volatile memory module 406 to read data from the rewritable non-volatile memory module 406; the memory erasing circuit is configured to issue an erase command sequence to the rewritable non-volatile memory module 406 to erase data from the rewritable non-volatile memory module 406; and the data processing circuit is configured to process data to be written into the rewritable non-volatile memory module 406 and data to be read from the rewritable non-volatile memory module 406. Each of the write command sequence, the read command sequence and the erase command sequence may include one or a plurality of program codes or instruction codes and is configured to instruct the rewritable non-volatile memory module 406 to perform corresponding writing, reading and erasing operations.

The host interface 504 is coupled to the memory management circuit 502 and configured to receive and identify commands and data transmitted from the host system 11. Namely, the commands and data transmitted by the host system 11 are transmitted to the memory management circuit 502 through the host interface 504. In the present exemplary embodiment, the host interface 504 complies with the SATA standard. However, it should be understood that the present disclosure is not limited thereto, and the host interface 504 may also comply with the PATA standard, the IEEE 1394 standard, the PCI Express standard, the USB standard, the SD standard, the UHS-I interface standard, the UHS-II interface standard, the MS standard, the MMC standard, the eMMC standard, the UFS standard, the CF standard, the IDE standard or other appropriate data transmission standards.

The memory interface 506 is coupled to the memory management circuit 502 for accessing the rewritable non-volatile memory module 406. In other words, the data to be written into the rewritable non-volatile memory module 406 is converted to an acceptable format for the rewritable non-volatile memory module 406 through the memory interface 506. To be specific, if the memory management circuit 502 intends to access the rewritable non-volatile memory module 406, the memory interface 506 transmits corresponding command sequences. For example, the command sequences may include a write command sequence instructing to write data, a read command sequence instructing to read data, an erasing command sequence instructing to erase data and a variety of corresponding command sequences configured to instruct to perform various memory operations (e.g., an operation of changing a read voltage level, an operation of performing a garbage collection procedure, and so on), which will not be repeatedly described one by one. The command sequences are, for example, generated by the memory management circuit 502 and transmitted to the rewritable non-volatile memory module 406 through the memory interface 506. The command sequences may include one or a plurality of signals or data on a bus. The signals or data may include instruction codes or program codes. For example, a read command sequence may include information, such as an identification code for reading, a memory address and so on.

The error checking and correcting circuit 508 is coupled to the memory management circuit 502 and configured to perform an error checking and correcting procedure for ensuring data integrity. To be specific, when the memory management circuit 502 receives a writing command from the host system 11, the error checking and correcting circuit 508 generates an error correcting code (ECC) and/or an error detecting code (EDC) corresponding to the write command, and the memory management circuit 502 writes the data corresponding to the write command and the corresponding ECC and/or EDC into the rewritable non-volatile memory module 406. Thereafter, when reading the data from the rewritable non-volatile memory module 406, the memory management circuit 502 simultaneously reads the ECC and/or EDC corresponding to the data, and the error checking and correcting circuit 508 performs the error checking and correcting procedure on the read data according to the ECC and/or EDC.

In the present exemplary embodiment, the error checking and correcting circuit 508 uses a low density parity code (LDPC). However, in another exemplary embodiment, the error checking and correcting circuit 508 may also use a BCH code, a convolutional code, a turbo code, or a bit flipping encoding/decoding algorithm.

In an exemplary embodiment, the memory control circuit unit 404 further includes a buffer memory 510 and a power management circuit 512. The buffer memory 510 is coupled to the memory management circuit 502 and configured to temporarily store the data and commands from the host system 11 or the data from the rewritable non-volatile memory module 406. The power management circuit 512 is coupled to the memory management circuit 502 and configured to control the power of the memory storage device 10.

In the present exemplary embodiment, the memory management circuit 502 configures logic units for mapping physical units in the rewritable non-volatile memory module 406. For example, in the present exemplary embodiment, the host system 11 access data in the rewritable non-volatile memory module 406 through logic addresses, and thus, each logic unit refers to a logic address. However, in another exemplary embodiment, each logic unit may also be refer to a logic sector, a logic page or composed of a plurality of successive logic addresses. Each logic unit is mapped to one or more physical units. In the present exemplary embodiment, a physical unit refers to a physical block. However, in another exemplary embodiment, a physical unit may also be a physical address, a physical sector, a physical page or composed of a plurality of successive physical addresses, which is not limited in the disclosure.

The memory management circuit 502 records a mapping relationship between the logic units and the physical units in a logic-physical mapping table. When the host system 11 intends to read data from the memory storage device 10 or write data into the memory storage device 10, the memory management circuit 502 may perform a data accessing operation on the memory storage device 10 according to the logic-physical mapping table.

In the present exemplary embodiment, the error checking and correcting circuit 508 encodes and decodes according to the LDPC algorithm. In the LDPC algorithm, a valid codeword is defined by using a check matrix (which is also referred to as a parity check matrix). Hereinafter, a parity check matrix is marked as a matrix H, and a codeword is marked as CW. According to an equation (1) below, if a parity check matrix H multiplied by a codeword CW is a zero vector, it represents that the codeword CW is a valid codeword. Therein, an operator [symbol] represents a modulo-2 matrix multiplication. In other words, a null space of the matrix H includes all the valid codewords. However, the disclosure is not intent to limit the content of the codeword CW. For example, the codeword CW may also include the ECC or the EDC generated by using any algorithms.

H [symbol] CW^{T}=0 (1)

Therein, a dimension of the matrix H is k-by-n, and a dimension of the codeword CW is 1-by-n. Therein, k and n are positive integers. The codeword CW includes message bits and parity bits. Namely, the codeword CW may be represented by [M P], in which a vector M is constituted by the message bits, and a vector P is constituted by the parity bits. A dimension of the vector M is 1-by-(n-k), and a dimension of the vector P is 1-by-k. Hereinafter, the message bits and the parity bits are collectively referred to as data bits. In other words, the codeword CW includes n data bits, in which a length of the message bits is (n-k) bits, and a length of the parity bits is k bits. Namely, a code rate of the codeword CW is (n-k)/n.

Generally, a generation matrix (marked as G hereinafter) is used during decoding, so that an equation (2) below may be satisfied by an arbitrary value of the vector M. Therein, a dimension of the generation matrix G is (n-k)-by-n.

M [symbol] G=[M P]=CW (2)

Therein, the codeword CW generated by the equation (2) is the valid codeword. Therefore, the equation (2) is substituted into the equation (1), and an equation (3) below may be obtained accordingly.

H [symbol] G^{T} [symbol] M^{T}=0 (3)

Since the vector M may be an arbitrary vector, an equation (4) below may definitely be satisfied. In other words, after the parity check matrix H is determined, the corresponding generation matrix G may also be determined.

H [symbol] G^{T}=0 (4)

When decoding for the codeword CW, a parity check procedure is first performed on the data bits in the codeword. For instance, the parity check matrix H may be multiplied by the codeword CW to generate a vector (hereinafter, marked as S, as shown in an equation (5) below). If the vector S is the zero vector, the codeword CW may be directly output. If the vector S is not the zero vector, it indicates that at least one error exists in the codeword CW, and the codeword CW is not the valid codeword.

H [symbol] CW^{T}=S (5)

A dimension of the vector S is k-by-1, in which each element is also referred to as a syndrome. If the codeword CW is not the valid codeword, the error checking and correcting circuit 508 performs a decoding procedure attempting to correct an error bit in the codeword CW.

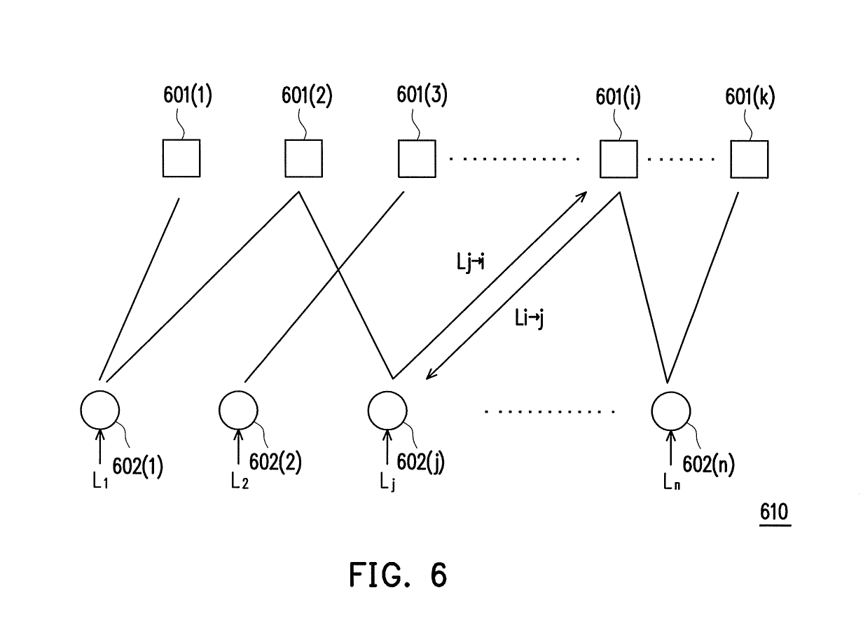

FIG. 6 is a schematic diagram illustrating belief propagation of a low density parity code (LDPC) algorithm according to an exemplary embodiment of the disclosure.

Referring to FIG. 6, the parity check matrix H may be represented as a belief propagation graph 610, including parity nodes 601(1) to 601(k) and message nodes 602(1) to 602(n). Each of the parity nodes 601(1) to 601(k) is corresponding to a syndrome, and each of the message nodes 602(1) to 602(n) is corresponding to a data bit. A corresponding relationship between the data bits and the syndromes (i.e., a connection relationship between the message nodes 602(1) to 602(n) and the parity nodes 601(1) to 601(k)) is generated according to the parity check matrix H. Particularly, if an element of an ith row and a jth column in the parity check matrix H is 1, the ith parity node 601(i) is connected to jth message node 602(j), in which i and j are positive integers.

When the memory management circuit 502 reads n data bits (which forms a codeword) from the rewritable non-volatile memory module 106, the memory management circuit 502 (or the error checking and correcting circuit 508) also obtains reliability information (also referred to as channel reliability information) of each data bit. The reliability information is configured to represent a probability (or referred to as a reliance level) of one specific data bit to be decoded as “1” or “0”. For example, in graph 610, the message nodes 602(1) to 602(n) receive corresponding reliability information L₁ to Lₙ. Therein, the message nodes 602(1) receives the reliability information L₁ of a 1^{st} data bit, and the message nodes 602(j) receives the reliability information Lⱼ of the jth data bit.

The error checking and correcting circuit 508 performs a decoding procedure according to the structure of the graph 610 and the channel reliability information L₁ to Lₙ. In the present exemplary embodiment, the decoding procedure performed by the error checking and correcting circuit 508 is an iterative decoding process. In the iterative decoding process, each of the message nodes 602(1) to 602(n) calculates the reliability information to each of the parity nodes 601(1) to 601(k), and each of the parity nodes 601(1) to 601(k) calculates the reliability information to each of the message nodes 602(1) to 602(n). The calculated reliability information is delivered along edges in the graph 610. For example, the reliability information transmitted by the parity node 601(i) to the message node 602(j) is reliability information L_{i→j}, and reliability information transmitted by the message node 602(j) to the parity node 601(i) is reliability information L_{j→i}. The reliability information is configured to represent a probability of one specific data bit to be decoded into “1” or “0”. For example, the reliability information L_{j→i} represents a reliance level (which may be positive or negative) of the jth data bit to be decoded into “1” or “0” calculated by the message node 602(j), and the reliability information L_{i→j} represents a reliance level of the jth data bit to be decoded into “1” or “0” calculated by the parity node 601(i). The message nodes 602(1) to 602(n) and the parity nodes 601(1) to 601(k) calculate reliability information to be output according to the input reliability information, which is approximate to a conditional probability of a data bit to be decoded into “1” or “0”. Thus, the process of delivering the reliability information is also referred to belief propagation.

As different algorithms are employed, the message nodes 602(1) to 602(n) and/or parity nodes 601(1) to 601(k) calculate different reliability information. For example, the error checking and correcting circuit 508 may employ a sum-product Algorithm, a min-sum algorithm, or a bit-flipping algorithm, and the disclosure is not intent to limit which algorithm is employed.

In the present exemplary embodiment, the iteration is continuously and repeatedly executed in the iterative decoding process to update the reliability information of at least a part of the data bits, until the valid codeword is successfully obtained, or times of executing the iteration reaches a default threshold value. For example, in each iteration of the iterative decoding process, the message nodes 602(1) to 602(n) transmit the reliability information to the parity nodes 601(1) to 601(k), and the parity nodes 601(1) to 601(k) transmit the reliability information to the message nodes 602(1) to 602(n).

Each time after the iteration is executed, the error checking and correcting circuit 508 calculates whether each data bit is to be decoded into a bit of “1” or “0” according to the current reliability information and verify each of the calculated data bits. For example, the error checking and correcting circuit 508 performs the parity check procedure to verify the calculated data bits. In the parity check procedure, the error checking and correcting circuit 508 multiplies the codeword generated by the data bits with its corresponding parity check matrix and thereby, determines whether the codeword is the valid codeword. If the generated codeword is the valid codeword, it represents a decoding success, and the iterative decoding process ends. If the generated codeword is not the valid codeword, the next iteration is executed. Additionally, if the times of the iteration of the iterative decoding process is over a default value, the iteration decoding operation also ends, which represents a decoding failure.

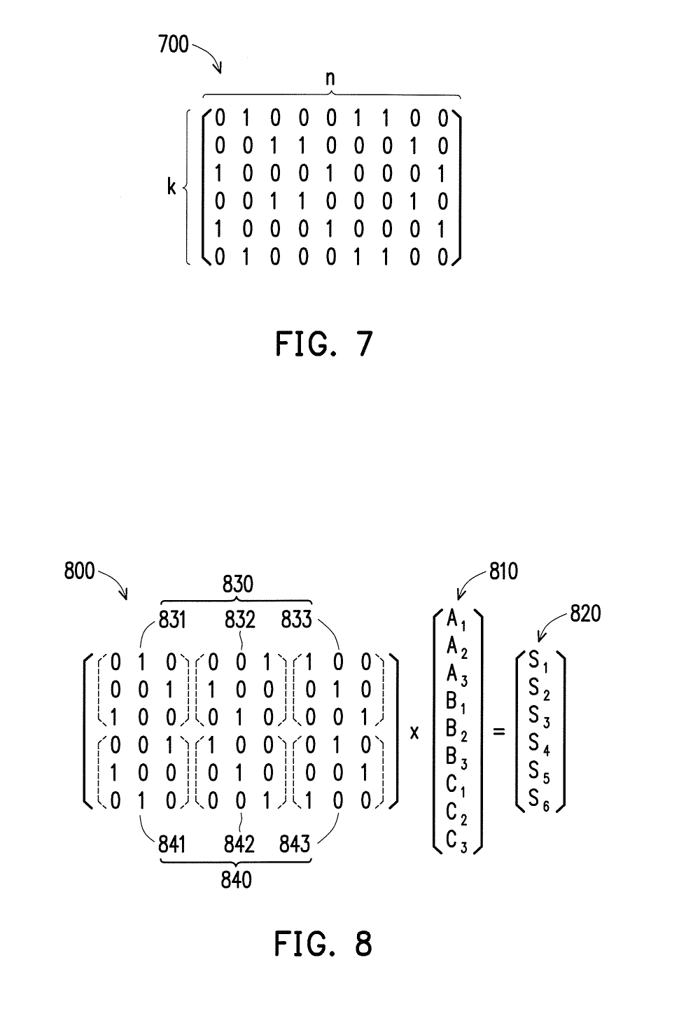

FIG. 7 is a schematic diagram illustrating a parity check matrix according to an exemplary embodiment of the disclosure.

Referring to FIG. 7, a dimension of parity check matrix 700 is 6-by-9, but the disclosure does not limit specific values that the positive integers k and n should be. Each row of the parity check matrix 700 represents a constraint. Taking the first row of the parity check matrix 700 as an example, if a specific codeword is a valid codeword, a bit of “0” is obtained after a modulo-2 addition is performed on the 2^{nd}, 6^{th} and 7^{th} bits in the codeword. It should be understood for a person of ordinary skill in the art how to encode by using the parity check matrix 700 and this, will not be repeatedly described. Additionally, the parity check matrix 700 is merely an exemplary matrix and construes no limitations to the disclosure.

When the memory management circuit 502 intends to write a plurality of bits into the rewritable non-volatile memory module 406, the error checking and correcting circuit 508 generates k bits (i.e., parity bits) corresponding to each (n-k) bits (i.e., message bits) to be written. The memory management circuit 502 writes the n bits (i.e., data bits) serving as a codeword into the rewritable non-volatile memory module 406.

The memory management circuit 502 receives a read command from the host system 11. The memory management circuit 502 transmits a read command sequence to the rewritable non-volatile memory module 406 according to the read command. The read command sequence instructs the rewritable non-volatile memory module 406 to read at least one physical unit. The rewritable non-volatile memory module 406 performs a corresponding reading operation (e.g., applies a read voltage to a specific physical unit to read data stored in at least one memory cell) according to the read command sequence and returns response data to the memory management circuit 502. The memory management circuit 502 receives the response data from the rewritable non-volatile memory module 406, and the error checking and correcting circuit 508 performs an iterative decoding process on the response data.

In the present exemplary embodiment, the memory management circuit 502 determines an offset threshold value. The memory management circuit 502 determines a check matrix (e.g., the parity check matrix 700 illustrated in FIG. 7) according to the determined offset threshold value. The error checking and correcting circuit 508 performs the aforementioned encoding and decoding procedure according to the check matrix. The description related to the encoding and decoding procedure is set forth in detail above and will not be repeated.

In the present exemplary embodiment, the determined check matrix includes a plurality of sub-matrices. The sub-matrices are grouped into at least one sub-matrix group. Each sub-matrix has a default dimension. Specifically, the determined offset threshold value is less than a default dimension value corresponding to the default dimension. For example, if the default dimension of each sub-matrix is 3-by-3, the default dimension value corresponding to the default dimension is “3”.

In the iterative decoding process, the error checking and correcting circuit 508 generates a data set corresponding to the received response data. The data set includes a plurality of groups. The error checking and correcting circuit 508 shifts the groups in the data set according to the determined offset threshold value and different sub-matrix groups of the determined check matrix to obtain a plurality of shift groups, such that an offset of each group of the data set with respect to each shifting (also referred to group shifting) is not over the determined offset threshold value. It should be noted that, the group shifting referred herein refers to that the bits of each group are shifted with each group as a unit. For example, if it is assumed that a certain group include elements of “A₁”, “A₂” and “A₃” which are sequentially permuted, after a group shifting operation with an offset of “1” (i.e., the offset=1) is performed on the certain group, the permutation sequence of the elements in the certain group is changed as the elements “A₃”, “A₁” and “A₂”, and the sequentially permuted elements “A₃”, “A₁” and “A₂” may be considered as a shift group with respect to the sequentially permuted elements “A₁”, “A₂” and “A₃”, and an offset of each of the sequentially permuted elements “A₃”, “A₁” and “A₂” with respect to each of the sequentially permuted elements “A₁”, “A₂” and “A₃” is “1”. Then, the error checking and correcting circuit 508 generates decoding reference data according to the shift groups. The decoding reference data is used in the iterative decoding process.

In an exemplary embodiment, the generated decoding reference data is a syndrome set (also referred to as a syndrome vector) corresponding to a parity check procedure and configured to verify whether a specific codeword is a valid codeword (or, whether the decoding successes). In an exemplary embodiment, the generated decoding reference data is a syndrome weight set (also referred to as a syndrome weight vector) corresponding to a bit-flipping algorithm and configured to determine which data bit is to be flipped. In an exemplary embodiment, the generated decoding reference data is a minimum value set (also referred to as a minimum vector) corresponding to a min-sum algorithm and configured to determine the reliability information of at least part of the data bits. Several exemplary embodiments will be provided to describe how to perform a group shift on a data sets in the iterative decoding process and generate corresponding decoding reference data.

FIG. 8 is a schematic diagram illustrating a parity check procedure according to an exemplary embodiment of the disclosure. In the present exemplary embodiment, the data set and the decoding reference data are used in a parity check procedure of the LDPC algorithm. For example, the data set refers to the codeword to be verified in the parity check procedure, and the decoding reference data is a syndrome set generated in the parity check procedure.

Referring to FIG. 8, the memory management circuit 502 determines an offset threshold value. In the present exemplary embodiment, the determined offset threshold value is “2”. The memory management circuit 502 determines a parity check matrix 800 corresponding to the determined offset threshold value. The parity check matrix 800 is used for encoding while a data storage operation is performed and for decoding while a data reading operation is performed.

In the present exemplary embodiment, the parity check matrix 800 includes sub-matrix groups 830 and 840. The sub-matrix groups 830 and 840 include sub-matrices 831 to 833 and sub-matrices 841 to 843 permuted in a row direction, respectively. Each of the sub-matrices 831 to 833 and 841 to 843 is a square matrix and has a default dimension. For example, the default dimension of each of the sub-matrices 831 to 833 and 841 to 843 is 3-by-3, and a default dimension value corresponding to the default dimension is “3”. The memory management circuit 502 constrains that in the determined parity check matrix 800, the default dimension value (i.e., “3”) corresponding to the default dimension of each of the sub-matrices 831 to 833 and 841 to 843 is greater than the predetermined offset threshold value (i.e., “2”). However, the determined parity check matrix may vary with the corresponding offset threshold value, as long as the condition that the default dimension value of each sub-matrix in the determined parity check matrix is greater than the predetermined offset threshold value is satisfied. For example, in another exemplary embodiment, the number of the sub-matrix groups in the parity check matrix may be more or less, the number of the sub-matrices in each sub-matrix group may be more or less, and the default dimension of each sub-matrix may be greater or smaller.

In the present exemplary embodiment, after the memory management circuit 502 transmits the read command sequence and receives the response data corresponding to the read command sequence, the error checking and correcting circuit 508 performs an iterative decoding process on the response data. In a specific iteration of the iterative decoding process, a codeword 810 is determined and is verified whether to be a valid codeword in a corresponding parity check procedure.

To be specific, in the parity check procedure corresponding to the codeword 810, the error checking and correcting circuit 508 obtains a result of matrix multiplication of the parity check matrix 800 and the codeword 810 and serves the result as a syndrome set 820. For example, a syndrome S₁ in the syndrome set 820 is obtained by performing a modulo-2 addition on bits A₂, B₃ and C₁ in the codeword 810 corresponding to positions having elements of 1 in the first row of the parity check matrix 800, a syndrome S₂ in the syndrome set 820 is obtained by performing a modulo-2 addition on bits A₃, B₁ and C₂ in the codeword 810 corresponding to positions having elements of 1 in the second row of the parity check matrix 800, a syndrome S₄ in the syndrome set 820 is obtained by performing a modulo-2 addition on bits A₃, B₁ and C₂ in the codeword 810 corresponding to positions having elements of 1 in the fourth row of the parity check matrix 800. In the same way, syndromes S₁ to S₆ in the syndrome set 820 are obtained. Thereafter, the error checking and correcting circuit 508 determines whether errors exists in the codeword 810 according to whether the syndrome set 820 is the zero vector (i.e., whether all of the syndrome S₁ to S₆ are “0”). For example, if all of the syndromes S₁ to S₆ are “0”, the error checking and correcting circuit 508 determines that no errors exits in the codeword 810 (i.e., the codeword 810 is the valid codeword) and outputs decoded data according to the codeword 810. However, if at least one of the syndromes S₁ to S₆ is “1”, the error checking and correcting circuit 508 determines that at least one error exists in the codeword 810. If the error checking and correcting circuit 508 determines that the codeword 810 has error and the times of the executed iteration does not yet reach the default threshold value, the error checking and correcting circuit 508 performs the next iteration on the codeword 810 and perform the parity check procedure again to verify the generated codeword. Additionally, in an exemplary embodiment, the decoding efficiency may be reinforced by mechanisms, such as reading the same physical unit again using a changed read voltage level or changing the decoding manner, which will be no longer described hereinafter.

In the present exemplary embodiment, the error checking and correcting circuit 508 does not actually perform the matrix multiplication as illustrated in FIG. 8. Instead, the error checking and correcting circuit 508 performs group shifting and the matrix addition on the codeword 810 corresponding to the sub-matrix groups 830 and 840 in the parity check matrix 800 to obtain the syndrome set 820. This is because in several cases, performing the matrix addition with respect to performing the matrix multiplication has a lower complexity and/or a higher computing speed. In other words, the error checking and correcting circuit 508 gradually generates the syndrome set 820 layer by layer. For example, the sub-matrix group 830 is the first layer and used to calculate the syndromes S₁ to S₃ in the syndrome set 820, and the sub-matrix group 840 is the second layer and used to calculate the syndromes syndrome S₄ to S₆ in the syndrome set 820.

In the present exemplary embodiment, the error checking and correcting circuit 508 groups a plurality of groups (also referred to as default groups) in the codeword 810 corresponding to the default dimension of each sub-matrix in the parity check matrix 800. For example, corresponding to the sub-matrix having the default dimension of 3-by-3, the bits A₁, A₂ and A₃ in the codeword 810 are grouped to the same default group (referred to as a first default group hereinafter), the bits B₁, B₂ and B₃ in the codeword 810 are grouped to the same default groups (referred to as a second default groups hereinafter), the bits C₁, C₂, C₃ in the codeword 810 are grouped to the same default group (referred to as a third default group). In a corresponding group shifting operation, each bit in the codeword 810 is shifted depending on which group the bit belong to. In other words, offsets of a plurality of bits belonging to the same group in one group shifting operation are the same, while offsets of a plurality of bits belonging to different groups in one group shifting operation may be the same or different. For example, in a group shifting operation corresponding to a specific layer, offsets of the bits A₁, A₂ and A₃ belonging to the first default group are the same; however, offsets of the bits A₁ and B₁ respectively belonging to the first default group and the second default groups may be the same or different.

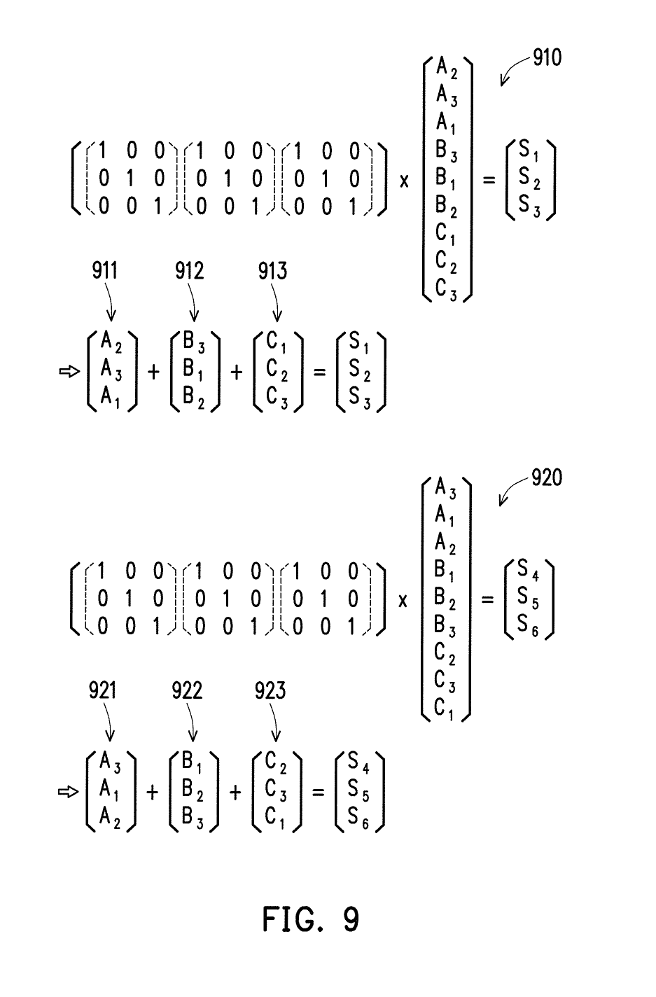

FIG. 9 is a schematic diagram of obtaining a syndrome set corresponding to the parity check procedure according to an exemplary embodiment of the disclosure.

Referring to FIG. 8 and FIG. 9, a group shifting operation corresponding to the sub-matrix group 830 (i.e., the first layer) is first performed. For example, corresponding to each position in the sub-matrix group 830 having the element of 1, the bits A₁, A₂ and A₃ in the codeword 810 are shifted as in the permutation of the bits A₂, A₃ and A₁, the bits B₁, B₂ and B₃ in the codeword 810 are shifted as in the permutation of the bits B₃, B₁ and B₂, and the bits C₁, C₂ and C₃ in the codeword 810 are not shifted. Therefore, a codeword 910 including the sequentially permuted bits A₂, A₃, A₁, B₃, B₁, B₂, C₁, C₂ and C₃ as illustrated in FIG. 9 is obtained.

In the present exemplary embodiment, the bits A₂, A₃ and A₁ in the codeword 910 are considered as belonging to a shift group 911 corresponding to the first default group, the bits B₃, B₁ and B₂ in the codeword 910 are considered as belonging to a shift group 912 corresponding to the second default group, the bits C₁, C₂ and C₃ in the codeword 910 are considered as belonging to a shift group 913 corresponding to the third default group. Therein, an offset of the shift group 911 with respect to the first default group is “1” (i.e., the offset=1), an offset of the shift group 912 with respect to the second default group is “2” (i.e., the offset=2), and an offset of the shift group 913 with respect to the third default group is “0” (i.e., the offset=0). Then, the error checking and correcting circuit 508 generates part of the syndromes in the syndrome set 820 according to the shift groups 911 to 913. For example, the error checking and correcting circuit 508 performs the matrix addition on the shift groups 911 to 913 to obtain the syndromes S₁ to S₃ in the syndrome set 820.

After the shift groups 911 to 913 are obtained, a group shifting operation corresponding to the sub-matrix group 840 (i.e., the second layer) is performed. For example, corresponding to each position in the sub-matrix group 840 having the element of 1, the bits A₂, A₃ and A₁ in the shift group 911 are shifted as in the permutation of the bits A₃, A₁ and A₂, the permutation of the bits B₃, B₁ and B₂ in the shift group 912 are shifted as in the permutation of the bits B₁, B₂ and B₃, and the bits C₁, C₂ and C₃ in the shift groups 913 are shifted as in the permutation of the bits C₂, C₃ and C₁. Therefore, a codeword 920 including the sequentially permuted bits A₃, A₁, A₂, B₁, B₂, B₃, C₂, C₃ and C₁ as illustrated in FIG. 9 is obtained.

In the present exemplary embodiment, the bits A₃, A₁ and A₂ in the codeword 920 are considered as belonging to a shift group 921 corresponding to the shift group 911, the bits B₁, B₂ and B₃ in the codeword 920 are considered as belonging to a shift group 922 corresponding to the shift group 912, and the bits C₂, C₃ and C₁ in the codeword 920 are considered as belonging to a shift group 923 corresponding to the shift groups 913. Therein, an offset of the shift group 921 with respect to the shift group 911 is “1” (i.e., the offset=1), an offset of the shift group 922 with respect to the shift group 912 is “1” (i.e., the offset=1), and an offset of the shift group 923 with respect to the shift group 913 is “1” (i.e., the offset=1). Then, the error checking and correcting circuit 508 generates another part of the syndromes in the syndrome set 820 according to the shift groups 921 to 923 For example, the error checking and correcting circuit 508 performs the matrix addition on the shift groups 921 to 923 to obtain the syndromes S₄ to S₆ in the syndrome set 820.

The memory management circuit 502 (or the error checking and correcting circuit 508) constrains that the offset of the group shifting performed corresponding to each sub-matrix group (i.e., each layer) is not over the determined offset threshold value. For example, in the exemplary embodiments illustrated in FIG. 8 and FIG. 9, the offset threshold value is set to “2”, and thus, the offset of each shift groups 911 to 913 with respect to an corresponding group in the codeword 810 is not over “2”, and the offset of each of the shift groups 921 to 923 with respect to the shift groups 911 to 913, respectively, is also not over “2”. For example, during the operation of performing the group shifting corresponding to the sub-matrix group 830 (i.e., the first layer) to generate the shift groups 911 to 913, the offset of each bit in the codeword 810 may be “0”, “1” or “2”, which depends on the group to which the bit belongs, and during the operation of performing the group shifting corresponding to the sub-matrix group 840 (i.e., the second layer) to generate the shift groups 921 to 923, the offset of each bit in the codeword 920 may be “0”, “1” or “2”, which depends on the group to which the bit belongs. Additionally, in another exemplary embodiment of FIG. 8 and FIG. 9, if the offset threshold value is set to “1”, the offset with respect to the bits in each shift group is not over “1” in each group shifting operation.

In an exemplary embodiment, if the syndrome set generated in the parity check procedure is not the zero vector (e.g., at least one of the syndromes S₁ to S₆ in FIG. 8 is “1”), it represents that at least one error exists in the currently verified codeword. Thus, a bit-flipping algorithm may be used to quickly determine which bit in the codeword is to be flipped, for example, a value of a certain bit is changed from “0” to “1”, or from “1” to “0”, to attempt to correct the error in the codeword. In the bit-flipping algorithm, a syndrome weight set corresponding to the syndrome set is calculated, and at least one bit in the codeword is flipped according to the syndrome weight set. In an exemplary embodiment, the group shifting is performed on a plurality of groups in the data set to obtain the corresponding decoding reference data, such that the complexity of calculating the syndrome weight set may be reduced, and/or the computing speed may be increased. However, in another exemplary embodiment, if it is determined that the currently verified codeword has an error, other decoding algorithms may also be used to correct the error in the codeword.

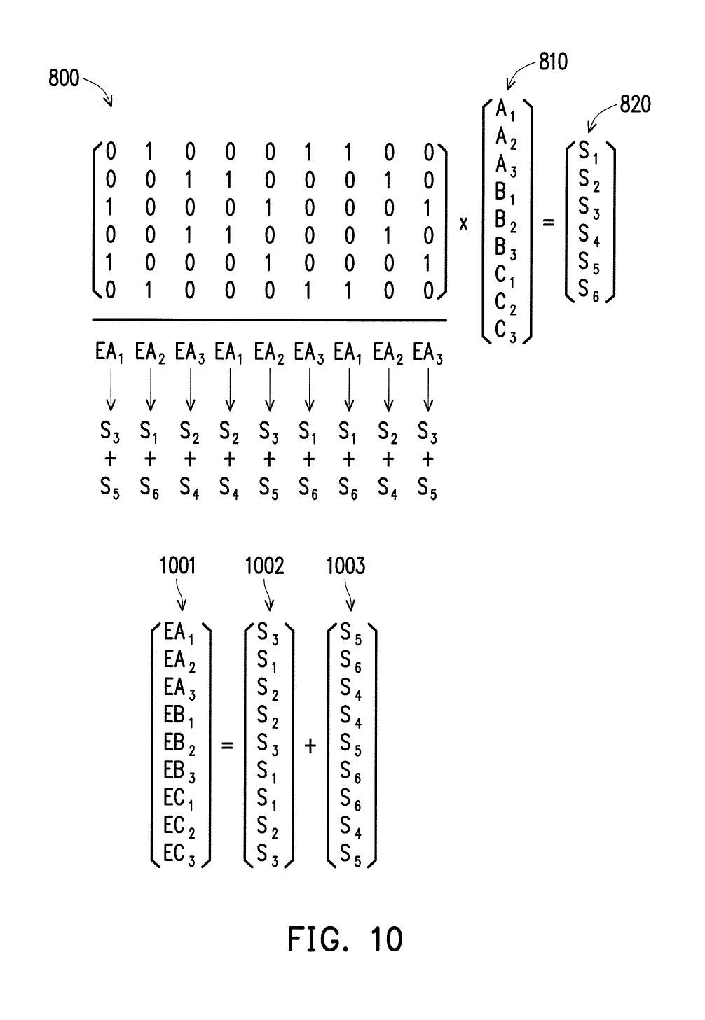

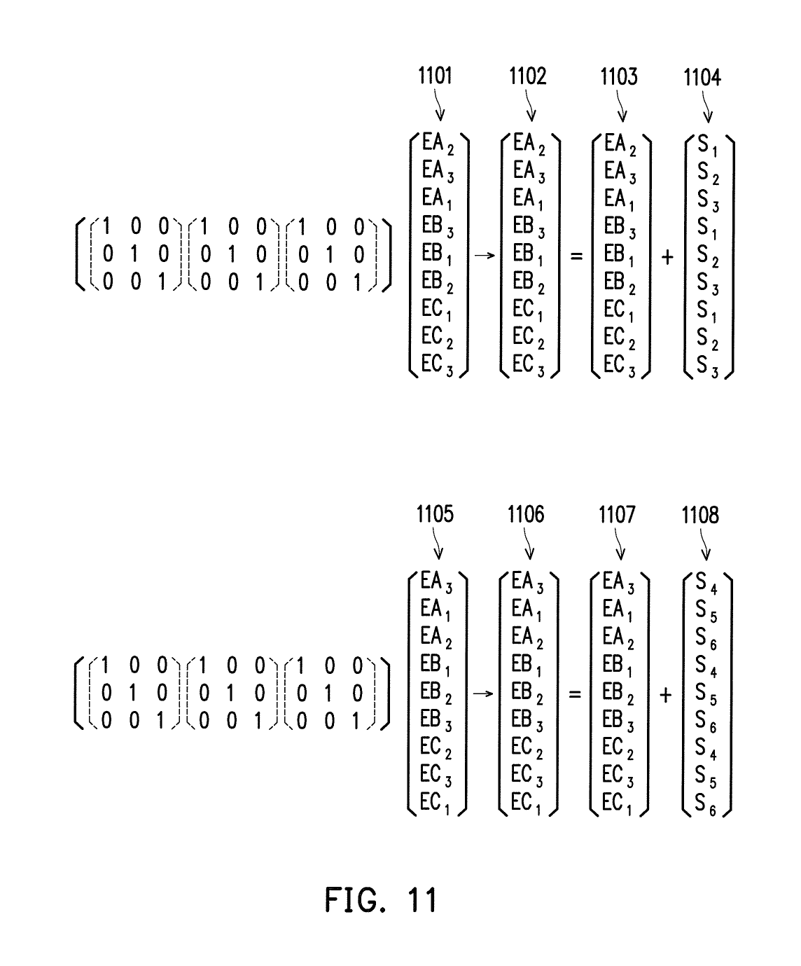

FIG. 10 and FIG. 11 are schematic diagrams of obtaining a syndrome set corresponding to the bit-flipping algorithm according to another exemplary embodiment of the disclosure. In the present exemplary embodiment, both the data set and the decoding reference data are used in the bit-flipping algorithm. For example, the data set refers to the syndrome weight set to be updated in the bit-flipping algorithm, and the decoding reference data refers to the updated syndrome weight set in the bit-flipping algorithm.

Referring to FIG. 10, after the syndrome set 820 is obtained, a syndrome weight set 1001 is determined in the bit-flipping algorithm. For example, the syndrome weight set 1001 includes syndrome weights EA₁, EA₂, EA₃, EB₁, EB₂, EB₃, EC₁, EC₂ and EC₃ permuted in an order. Therein, the syndrome weights EA₁, EA₂, EA₃, EB₁, EB₂, EB₃, EC₁, EC₂ and EC₃ are corresponding to the bits A₁, A₂, A₃, B₁, B₂, B₃, C₁, C₂ and C₃ in the codeword 810, respectively. The syndrome weight set 1001 may be used to represent a degree of each bit of the codeword 810 participating in the error existing in the codeword 810. For example, according to the parity check matrix 800, the bit A₁ participates in the calculation of the syndromes S₃ and S₅, and thus, the syndrome weight EA₁ corresponding to the bit A₁ may be calculated according to the syndromes S₃ and S₅. For example, the syndromes S₃ and S₅ may be added with each other to obtain the syndrome weight EA₁. Moreover, according to the parity check matrix 800, the bit A₂ participates in the calculation of the syndromes S₁ and S₆, and thus, the syndrome weight EA₂ corresponding to the bit A₂ may be calculated according to the syndromes S₁ and S₆. For example, the syndrome S₁ and S₆ may be added with each other to obtain the syndrome weight EA₂. Specifically, the addition used to calculate the syndrome weights in this case refers to an ordinary addition, instead of the modulo-2 addition. For example, if both the syndromes S₃ and S₅ are “1”, the syndrome weight EA₁, which is “2”, is obtained by adding the syndrome S₃ with syndrome S₅. In the same way, the syndrome weight set 1001 is obtained according to the parity check matrix 800 and the syndrome set 820.

In the bit-flipping algorithm, if a syndrome weight corresponding to a certain bit in the codeword has a large value, it represents that the bit is highly probable to be an error bit, and thus, it is highly probable that the error may be corrected by flipping the bit. In contrast, if a syndrome weight corresponding to a certain bit in the codeword is small, it represents that the bit is less probable to be an error bit, and thus, it is less probable that the error may be corrected by flipping the bit. Generally, the operation of obtaining the syndrome weight set 1001 according to the parity check matrix 800 and the syndrome set 820 may be equivalent to the operation of obtaining the syndrome weight set 1001 by adding a vector 1002 with a vector 1003. Therein, elements in the vector 1002 include the syndromes S₁ to S₃, and elements in the vector 1003 include the syndromes S₄ to S₆. Positions of the syndromes S₁ to S₃ in the vector 1002 are determined according to the parity check matrix 800, and positions of the syndromes S₄ to S₆ in the vector 1003 are also determined according to the parity check matrix 800.

In the present exemplary embodiment, the error checking and correcting circuit 508 also generates the syndrome weight set 1001 gradually with each layer as the unit. For example, the sub-matrix group 830 is the first layer and configured to perform a first update operation for the syndrome weight set, and the sub-matrix group 840 is the second layer and configured to perform a second update operation for the syndrome weight set. In the present exemplary embodiment, the error checking and correcting circuit 508 groups a plurality of syndrome weights in the vector 1001 into a plurality of default groups. For example, the syndrome weights EA₁, EA₂ and EA₃ belong to the first default group, the syndrome weights EB₁, EB₂ and EB₃ belong to the second default groups, and the syndrome weights EC₁, EC₂ and EC₃ belong to the third default group.

Referring to FIG. 11, the group shifting operation corresponding to the sub-matrix group 830 (i.e., the first layer) is first performed. For example, corresponding to the positions having the element of 1 in the sub-matrix group 830, the syndrome weights EA₁, EA₂ and EA₃ belonging to the first default group are shifted as in the permutation of the syndrome weights EA₂, EA₃ and EA₁, the syndrome weights EB₁, EB₂ and EB₃ belonging to the second default groups are shifted as in the permutation of the bits EB₃, EB₁, EB₂, and the syndrome weights EC₁, EC₂ and EC₃ belonging to the third default group are not shifted. Therefore, a vector 1101 including the sequentially permuted syndrome weights EA₂, EA₃, EA₁, EB₃, EB₁, EB₂, EC₁, EC₂ and EC₃ illustrated in FIG. 11 is obtained. For example, the syndrome weights EA₂, EA₃ and EA₁ in the vector 1101 belong to a shift group with respect to the first default group; the syndrome weights EB₃, EB₁ and EB₂ in the vector 1101 belong to a shift group with respect to the second default group, and the syndrome weights EC₁, EC₂ and EC₃ in the vector 1101 belong to a shift group with respect to the third default group.

Afterwards, the error checking and correcting circuit 508 generates a vector 1102 by using vectors 1103 and 1104. Therein, all elements are permuted in the same way in the vectors 1101 to 1103, as illustrated in FIG. 11. Additionally, initial values of all the elements in the vector 1103 are set to “0”. In the present exemplary embodiment, the operation of generating the vector 1102 may also be considered as an operation of updating the vector 1103 as the vector 1102. For example, in the operation of updating the vector 1103 as the vector 1102, the syndrome weights EA₂, EA₃ and EA₁ in the vector 1103 are respectively added with the syndromes S₁, S₂ and S₃ in the vector 1104 to obtain the updated syndrome weights EA₂, EA₃ and EA₁ in the vector 1102, the syndrome weights EB₃, EB₁ and EB₂ in the vector 1103 are respectively added with the syndromes S₁, S₂ and S₃ in the vector 1104 to obtain the updated syndrome weights EB₃, EB₁ and EB₂ in the vector 1102, and the syndrome weights EC₁, EC₂ and EC₃ in the vector 1103 are respectively added with the syndrome weights S₁, S₂ and S₃ in the vector 1104 to obtain the updated syndrome weights EC₁, EC₂ and EC₃ in the vector 1102.

After the vector 1102 is obtained, the group shifting operation corresponding to the sub-matrix group 840 (i.e., the second layer) is performed. For example, corresponding to the positions having the element of 1 in the sub-matrix group 840, the syndrome weights EA₂, EA₃ and EA₁ in the vector 1102 are shifted as in the permutation of the syndrome weights EA₃, EA₁ and EA₂, the syndrome weights EB₃, EB₁ and EB₂ in the vector 1102 are shifted as in the permutation of the syndrome weights EB₁, EB₂ and EB₃, and the syndrome weights EC₁, EC₂ and EC₃ in the vector 1102 are shifted as in the permutation of the syndrome weights EC₂, EC₃ and EC₁. Therefore, a vector 1105 including the sequentially permuted syndrome weights EA₃, EA₁, EA₂, EB₁, EB₂, EB₃, EC₂, EC₃ and EC₁ as illustrated in FIG. 11 is obtained.

Afterwards, the error checking and correcting circuit 508 generates a vector 1106 by using vectors 1107 and 1108. Therein, all elements are permuted in the same way in the vectors 1105 to 1107, as illustrated in FIG. 11. Additionally, the operation of generating the vector 1106 may also be considered as an operation of updating the vector 1107 as the vector 1106. For example, in the operation of updating the vector 1107 as the vector 1106, the syndrome weights EA₃, EA₁ and EA₂ in the vector 1107 are respectively added with the syndromes S₄, S₅ and S₆ in the vector 1108 to obtain the updated syndrome weights EA₃, EA₁ and EA₂ in the vector 1106, the syndrome weights EB₁, EB₂ and EB₃ in the vector 1107 are respectively added with the syndromes S₄, S₅ and S₆ in the vector 1108 to obtain the updated syndrome weights EB₁, EB₂ and EB₃ in the vector 1106, and the syndrome weights EC₂, EC₃ and EC₁ in the vector 1107 are respectively added with the syndromes S₄, S₅ and S₆ in the vector 1108 to obtain the updated syndrome weights EC₂, EC₃ and EC₁ in the vector 1106. The generated vector 1106 includes the syndrome weights corresponding to all bits in the codeword 810 illustrated in FIG. 10. In other words, the operation of sequentially updating the vectors 1102 and 1106 in the exemplary of FIG. 11 in replacement with the operation of adding the vectors 1102 with the vector 1003 illustrated in FIG. 10 may contribute to increasing the efficiency of calculating the syndrome weight set in the bit-flipping algorithm.

In an exemplary embodiment, if the error checking and correcting circuit 508 updates the reliability information in the iterative decoding process by using a sum-product algorithm, the operation of performing the group shifting on a plurality of groups in the data set to obtain the corresponding decoding reference data may also be applied to reduce the computation complexity of performing the min-sum algorithm and/or increasing the computing speed.

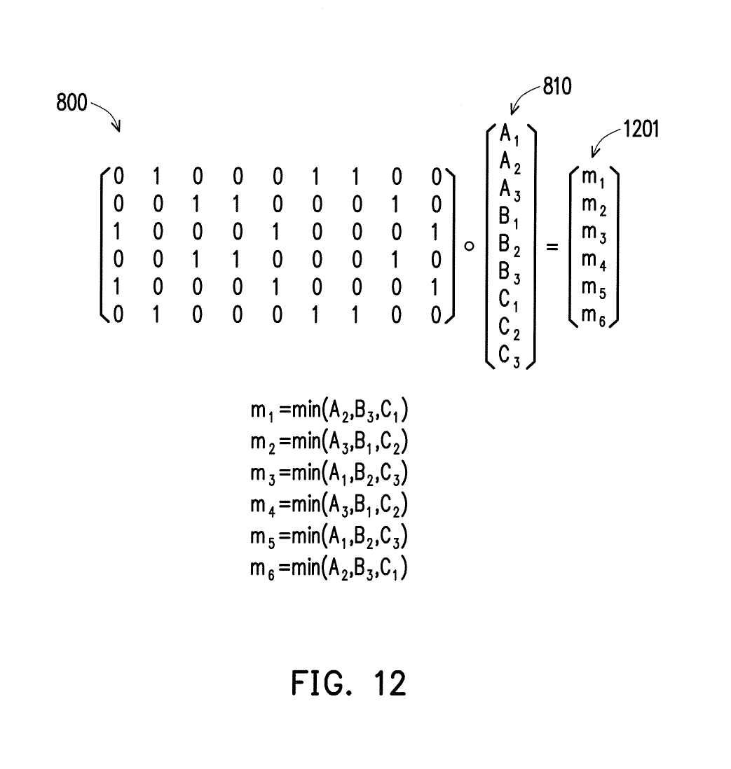

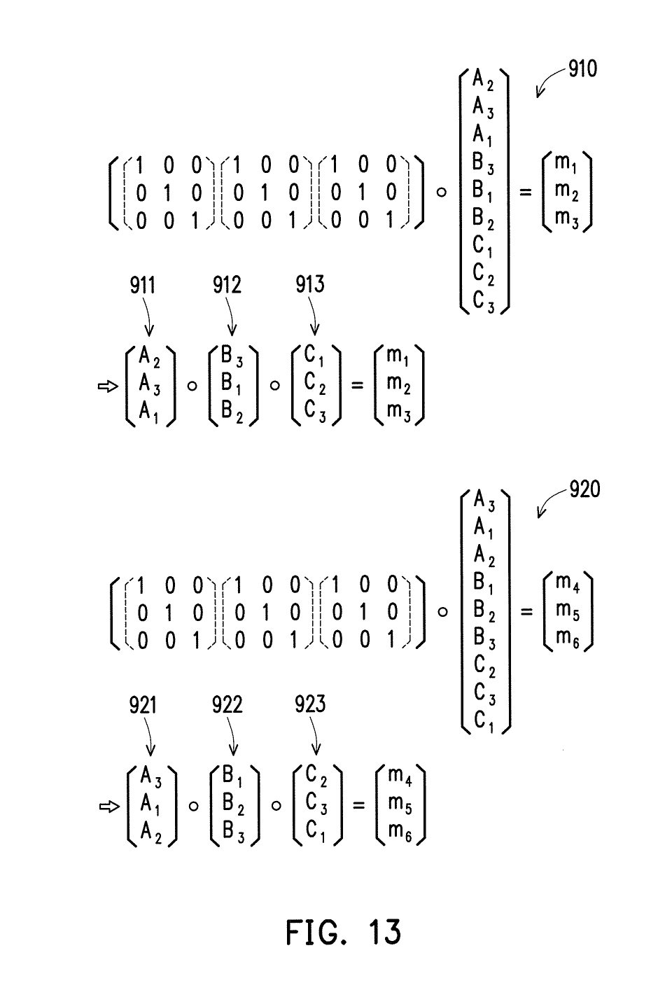

FIG. 12 and FIG. 13 are schematic diagrams of obtaining a minimum value set corresponding to a min-sum algorithm according to another exemplary embodiment of the disclosure. In the present exemplary embodiment, both the data set and the decoding reference data are used in the min-sum algorithm. For example, the data set refers to the codeword to be decoded, and decoding reference data is a minimum value set generated in the min-sum algorithm.

Referring to FIG. 12, in an iterative decoding process using the min-sum algorithm, the error checking and correcting circuit 508 performs multiple comparisons on different bits in the codeword 810 according to the parity check matrix 800 to generate a minimum value set 1201. For example, the minimum value set 1201 include minimum values m₁ to m₆. Therein, the minimum value m₁ is the minimum value selected from the bits A₂, B₃ and C₁ in the codeword 810, the minimum value m₂ is the minimum value selected from the bits A₃, B₁ and C₂ in the codeword 810, the minimum value m₃ is the minimum value selected from the bits A₁, B₂ and C₃ in the codeword 810, the minimum value m₄ is the minimum value selected from the bits A₃, B₁ and C₂ in the codeword 810, the minimum value m₅ is the minimum value selected from the bits A₁, B₂ and C₃ in the codeword 810, and the minimum value m₆ is the minimum value selected from the bits A₂, B₃ and C₁ in the codeword 810.

In the present exemplary embodiment, the error checking and correcting circuit 508, likewise, generates the minimum value set 1201 gradually with each layer as the unit. For example, the sub-matrix group 830 is the first layer and configured to calculate the syndromes m₁ to m₃ in the minimum value set 1201, and the sub-matrix group 840 is the second layer and configured to calculate the syndromes m₄ to m₆ in the minimum value set 1201. In the present exemplary embodiment, the error checking and correcting circuit 508 groups the bits in the codeword 810 into a plurality of default groups. For example, the bits A₁, A₂ and A₃ in the codeword 810 belong to the first default group, the bits B₁, B₂ and B₃ in the codeword 810 belong to the second default group, and the bits C₁, C₂ and C₃ in the codeword 810 belong to the third default group.

Referring to FIG. 13, the group shifting operation corresponding to the sub-matrix group 830 (i.e., the first layer) is first performed. For example, corresponding to the positions having the element of 1 in the sub-matrix group 830, the bits A₁, A₂ and A₃ in the codeword 810 are shifted as in the permutation of the bits A₂, A₃, A₁, the bits B₁, B₂ and B₃ in the codeword 810 are shifted as in the permutation of the bits B₃, B₁ and B₂, and the bits C₁, C₂ and C₃ in the codeword 810 are not shifted. Therefore, a codeword 910 including the sequentially permuted bits A₂, A₃, A₁, B₃, B₁, B₂, C₁, C₂ and C₃ as illustrated in the FIG. 13 is obtained. For example, the bits A₂, A₃ and A₁ in the codeword 910 belong to a shift group 911 with respect to the first default group, the bits B₃, B₁ and B₂ in the codeword 910 belong to a shift group 912 with respect to the second default group, and the bits C₁, C₂, C₃ in the codeword 910 belong to a shift group 913 with respect to the third default group.

Afterwards, the error checking and correcting circuit 508 selects minimum values from the bits located at specific positions in the shift groups 911 to 913 to generate the syndromes m₁ to m₃ in the minimum value set 1201. For example, the error checking and correcting circuit 508 selects the minimum value from the bits A₂, B₃ and C₁ located at the first position of each group in the shift groups 911 to 913 and serves it as m₁, selects the minimum value from the bits A₃, B₁ and C₂ located at the second position of each group in the shift groups 911 to 913 and serves it as m₂, and selects the minimum value from the bits A₁, B₂ and C₃ located at the third position of each group in the shift groups 911 to 913 and serves it as m₃.

After the shift groups 911 to 913 are obtained, the group shifting operation corresponding to the sub-matrix group 840 (i.e., the second layer) is performed. For example, corresponding to the positions having the element of 1 in the sub-matrix group 840, the bits A₂, A₃ and A₁ in the shift group 911 are shifted as in the permutation of the bits A₃, A₁ and A₂, the bits B₃ and B₁, B₂ in the shift groups 912 are shifted as in the permutation of the bits B₁, B₂ and B₃, and the bits C₁, C₂ and C₃ in the shift groups 913 are shifted in the permutation of the bits C₂, C₃, C₁. Therefore, a codeword 920 including the sequentially permuted bits A₃, A₁, A₂, B₁, B₂, B₃, C₂, C₃ and C₁ as illustrated in FIG. 13 is obtained. For example, the bits A₃, A₁ and A₂ in the codeword 920 are considered as belonging to the shift group 921 corresponding to the shift group 911, the bits B₁, B₂ and B₃ in the codeword 920 are considered as belonging to the shift group 922 corresponding to the shift group 912, and the bitsC₂, C₃ and C₁ in the codeword 920 are considered as belonging to the shift group 923 corresponding to the shift group 913.

Afterwards, the error checking and correcting circuit 508 selects minimum values from the bits located at specific positions in the shift groups 921 to 923 to generate the syndromes m₄ to m₆ in the minimum value set 1201. For example, the error checking and correcting circuit 508 selects the minimum value from the bits A₃, B₁ and C₂ located at the first position of each group in the shift groups 921 to 923 and serves it as m₄, selects the minimum value from the bits A₁, B₂ and C₃ located at the second position of each group in the shift groups 921 to 923 and serves it as m₅, and selects the minimum value from the bits A₂, B₃ and C₁ located at the third position of each group in the shift groups shift groups 921 to 923 and serves it as m₆. Thereby, minimum value set 1201 used in the min-sum algorithm may be obtained and the computation efficiency may be increased.

Based on the above, in the exemplary embodiments, even the aforementioned operations are respectively corresponding to different stages of the iterative decoding process and/or corresponding to different decoding algorithms, the operations of setting the offset threshold value, setting the parity check matrix, setting the groups in the data set, and the operations of performing the group shifting operation corresponding to each layer in the data set are the same or similar. In other words, for different stage in the iterative decoding process and/or different decoding algorithms, different kinds of data may be served as the data set and different kinds of logical operations may be performed according to the shifted groups.

In an exemplary embodiment, the determined offset threshold value is negatively correlated to a column weight corresponding to the employed parity check matrix. Therein, the column weight of the parity check matrix is corresponding to the number of elements of 1 contained in a certain column in the parity check matrix. For example, as the offset threshold value becomes greater, the number of elements of 1 contained in a certain column of the employed parity check matrix may be smaller, while as the offset threshold value becomes smaller, the number of elements of 1 contained in a certain column of the employed parity check matrix may be more. In an exemplary embodiment, the column weight of the parity check matrix is corresponding to the number of elements of 1 contained in a column which contains the greatest number of elements of 1 in the parity check matrix. For example, in a certain parity check matrix, a certain column contains two elements of 1, and another column contains three elements of 1, and thus, the column weight of the parity check matrix may be determined as “3”.

In an exemplary embodiment, the determined offset threshold value is equal to or greater than a minimum threshold value obtained by dividing the default dimension value of the parity check matrix by the column weight thereof. For example, the determined offset threshold value satisfies with equation (6) below.

$$\frac{P\_SIZE}{COL\_WT} \leq X \leq P\_SIZE - 1 \qquad ( 6 )$$

Therein, X is an offset threshold value, P_SIZE is a default dimension value of a parity check matrix, and COL_WT is a column weight of the parity check matrix.

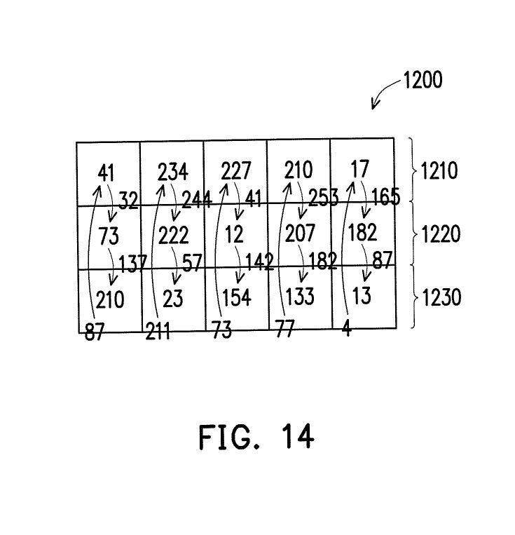

FIG. 14 is a schematic diagram of the group shifting according to an exemplary embodiment of the disclosure.

Referring to FIG. 14, it is assumed that a parity check matrix 1200 includes sub-matrix groups 1210, 1220 and 1230. Each of the sub-matrix groups 1210, 1220 and 1230 includes 5 sub-matrices. In FIG. 12, each block represents a sub-matrix, and the default dimension of each sub-matrix is 256-by-256. In FIG. 14, a value in each sub-matrix (i.e., each block) refers to an offset of a group in the data set that has to be shifted correspondingly to a certain layer. For example, values 41, 234, 227, 210 and 17 marked in the first to the fifth sub-matrices in the sub-matrix group 1210 represent that offsets of a plurality of groups in the data set to be shifted correspondingly to the first layer of the parity check matrix 1200 are 41, 234, 227, 210 and 17, respectively, and values 73, 222, 12, 207 and 182 marked in the first to the fifth sub-matrices in the sub-matrix group 1220 represent that offsets of a plurality of groups in the data set to be shifted correspondingly to the second layer of the parity check matrix 1200 are 73, 222, 12, 207 and 182, respectively, and values 210, 23, 154, 133 and 13 marked in the first to the fifth sub-matrices in the sub-matrix group 1230 represent that offsets of a plurality of groups in the data set to be shifted correspondingly to the third layer of the parity check matrix 1200 are 210, 23, 154, 133 and 13, respectively.

In an exemplary embodiment of FIG. 14, the memory management circuit 502 may select an arbitrary integer from a range of “85.3” to “255” and serve it as an offset threshold value to be used, and employs the parity check matrix 1200 with a column weight of “3”. For example, the column weight “3” is determined by substituting the offset threshold value into the equation (6). The memory management circuit 502 (or the error checking and correcting circuit 508) constrains that the value in each sub-matrix (i.e., each block) is not over the determined offset threshold value.

In addition, referring to FIG. 14, after the group shifting operation corresponding to the first layer of the parity check matrix 1200 is performed on the data set, a plurality of shift groups in the data set are further shifted for 32, 244, 41, 253 and 165 respectively, so as to reach the offsets of the data set corresponding to the second layer of the parity check matrix 1200. Similarly, after the group shifting operation corresponding to the second layer of the parity check matrix 1200 is performed on the data set, a plurality of shift groups in the data set are further shifted for 137, 57, 142, 182 and 87 respectively, so as to reach the offsets of the data set corresponding to the third layer of the parity check matrix 1200, after the group shift corresponding to the third layer of the parity check matrix 1200 is performed on the data set, a plurality of shift groups in the data set are further shifted for 87, 211, 73, 77 and 4 respectively, so as to return to the offsets of the data set corresponding to the first layer of the parity check matrix 1200.

In an exemplary embodiment, at least one selector is configured in the error checking and correcting circuit 508 to perform the group shifting of the data set. For example, According to an exemplary embodiment of FIG. 12, corresponding to the first layer of the parity check matrix 1200, a plurality of selectors of the error checking and correcting circuit 508 collectively shift a plurality of default groups in a data set as a plurality of first shift groups meeting the offsets 41, 234, 227, 210 and 17, corresponding to the second layer of the parity check matrix 1200, the selectors collectively shift the first shift groups as a plurality of second shift groups meeting the offsets 73, 222, 12, 207 and 182, and then, corresponding to the third layer of the parity check matrix 1200, the selectors collectively shift the second shift groups as other groups meeting the offsets 210, 23, 154, 133 and 13.

In an exemplary embodiment, the determination of the offset threshold value and the constraint that the offsets for performing each group shifting are not over the offset threshold value are for reducing the number of the selectors required. For example, if an ordinary stage shifter structure is employed, at least 8 selectors should be configured therein for supporting the parity check matrix 1200 with the default dimension of 256-by-256. However, in an exemplary embodiment of FIG. 12, with the constraint that the offsets for performing each group shifting are not over the offset threshold value, only 7 or fewer selectors may be disposed in the error checking and correcting circuit 508 in a scenario where the ordinary stage shifter structure is employed. Moreover, in some shifter structures, the selectors may be substituted by shift registers.

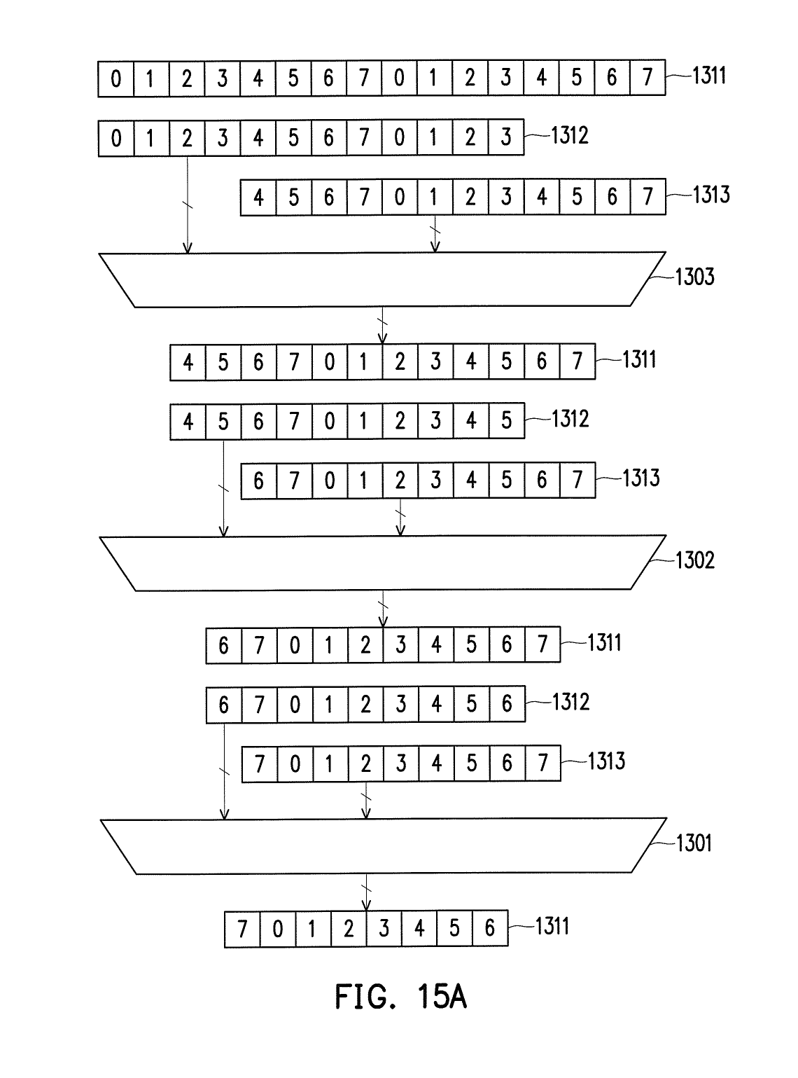

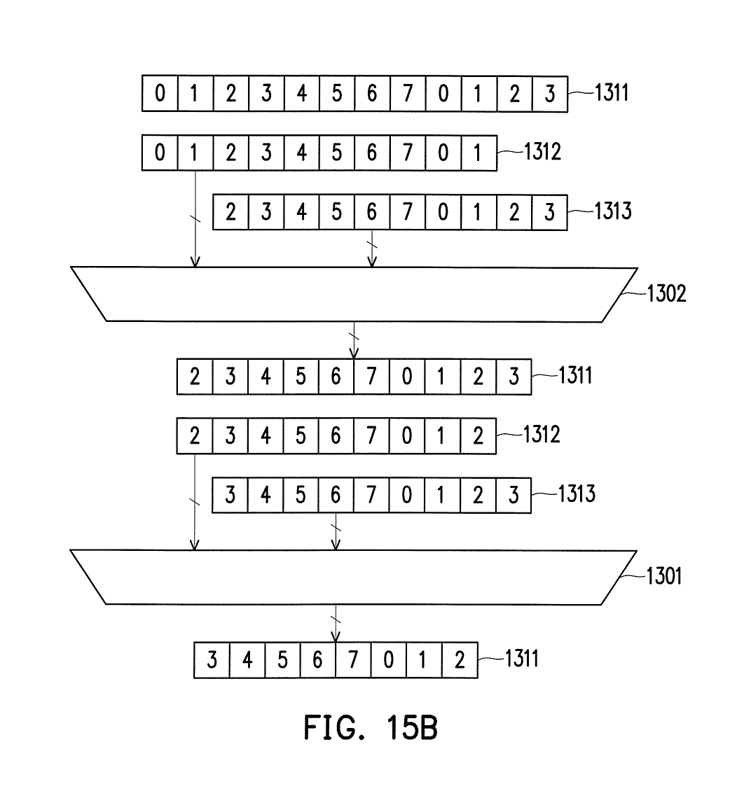

FIG. 15A and FIG. 15B are schematic diagrams illustrating a stage shifter structure according to an exemplary embodiment of the disclosure. To simplify, the shifting of a data set containing 8 bits is illustrated for example. However, in another exemplary embodiment, the data set that the group shifting operation is to be performed to may contain more or fewer bits.

Referring to FIG. 15A, if the offset for performing each group shifting is not constrained, then, at least 3 selectors 1301, 1302 and 1303 have to be configured in the error checking and correcting circuit 508 in order to support the maximum offset of 8 (e.g., shifting a codeword 01234567 as a codeword 70123456). However, referring to FIG. 15B, if the maximum of offset is limited to 3 (e.g., shifting the codeword 01234567 as a codeword 34567012) according to an exemplary embodiment of the disclosure, only two selectors 1301 and 1302 have to be configured in the error checking and correcting circuit 508. Moreover, registers 1311, 1312 and 1313 are configured to store the bits to be process in each stage.

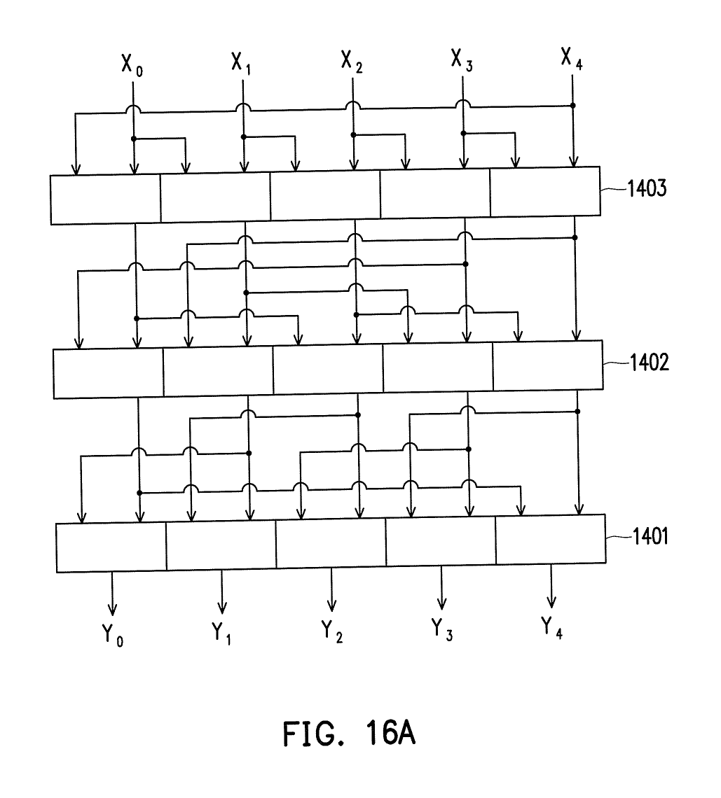

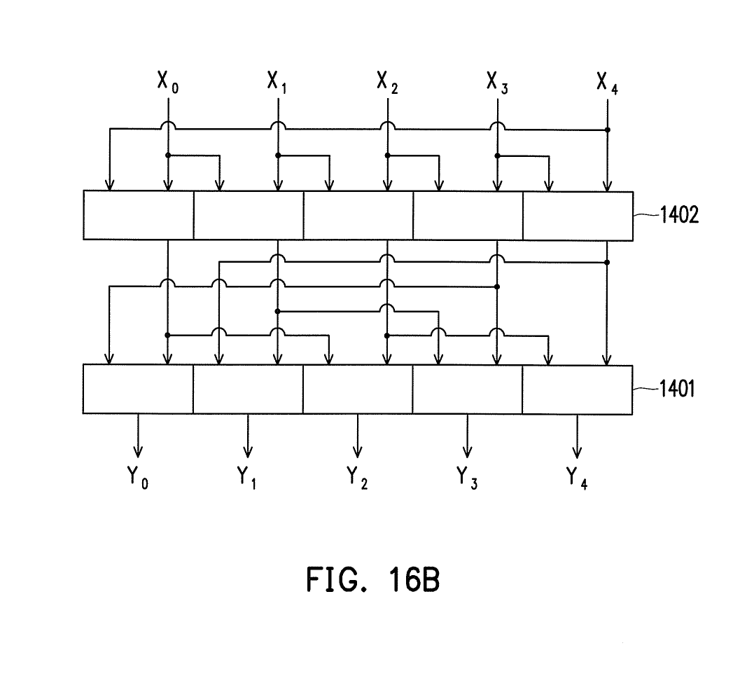

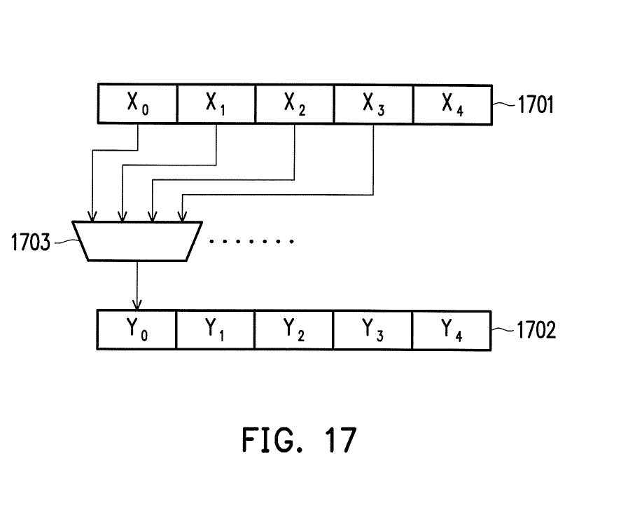

FIG. 16A and FIG. 16B are schematic diagrams illustrating a barrel shifter structure according to an exemplary embodiment of the disclosure.

Referring to FIG. 16A, if the offset for performing each group shifting is not constrained, at least 3 shift registers 1401, 1402 and 1403 have to be configured in the error checking and correcting circuit 508 in correspondence to 5 inputs X₀ to X₄. However, referring to FIG. 16B, if the offset for performing each group shifting is constrained according to the offset threshold value in an exemplary embodiment of the disclosure, only 2 shift registers 1401 and 1402 have to be configured in the error checking and correcting circuit 508. Moreover, Y₀ to Y₄ are output bits after the group shifting is performed.

FIG. 17 is a schematic diagram illustrating a reduced shifter structure according to another exemplary embodiment of the disclosure.

Referring to FIG. 17, in the condition that the offset for performing each group shifting is constrained according to the offset threshold value, a bit X₅ in a register 1701 is not read, and thereby, the number of selectors 1703 for performing the group shifting may also be reduced. Moreover, a register 1702 is configured to store output bits.

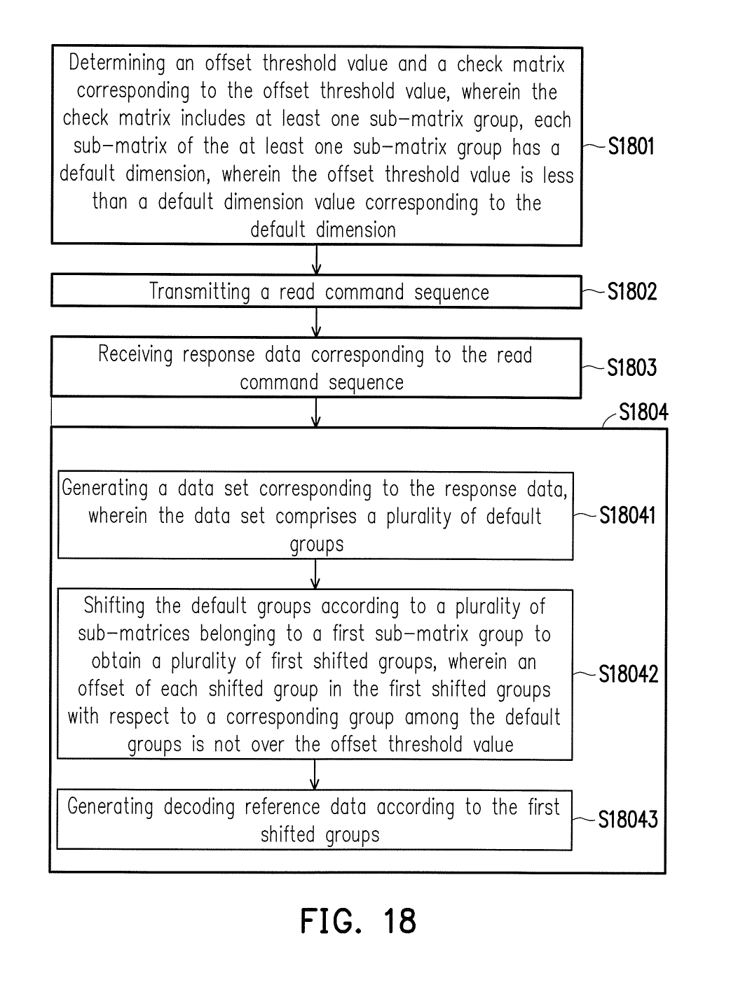

FIG. 18 is a flowchart illustrating a decoding method according to an exemplary embodiment of the disclosure.

Referring to FIG. 18, in step S1801, an offset threshold value and a check matrix corresponding to the offset threshold value are determined. The check matrix includes at least one sub-matrix group, each sub-matrix in the sub-matrix group has a default dimension, and the offset threshold value is less than the default dimension value corresponding to the default dimension, and the sub-matrix group includes a first sub-matrix group. In step S1802, a read command sequence is transmitted. The read command sequence instructs to read a physical unit of the rewritable non-volatile memory module. In step S1803, response data corresponding to the read command sequence is received. In step S1804, an iterative decoding process is performed on the response data. The iterative decoding process in step S1804 at least includes steps S18041 to S18043. In step S18041, a data set corresponding to the response data is generated. The data set includes a plurality of default groups. In step S18042, the default groups are shifted according to a plurality of sub-matrices belonging to the first sub-matrix group to obtain a plurality of first shift groups. An offset of each shift group in the first shift groups with respect to a corresponding group among the default groups is not over the offset threshold value. In step S18043, decoding reference data is generated according to the first shift groups.

However, each step of FIG. 18 has been described in detail above and thus, will not be repeated. It should be noted that each step of FIG. 18 may be implemented as a plurality of program codes or circuits, which is not limited in the disclosure. Moreover, the method illustrated in FIG. 18 may be operated with the exemplary embodiments above or solely, which is not limited in the disclosure.

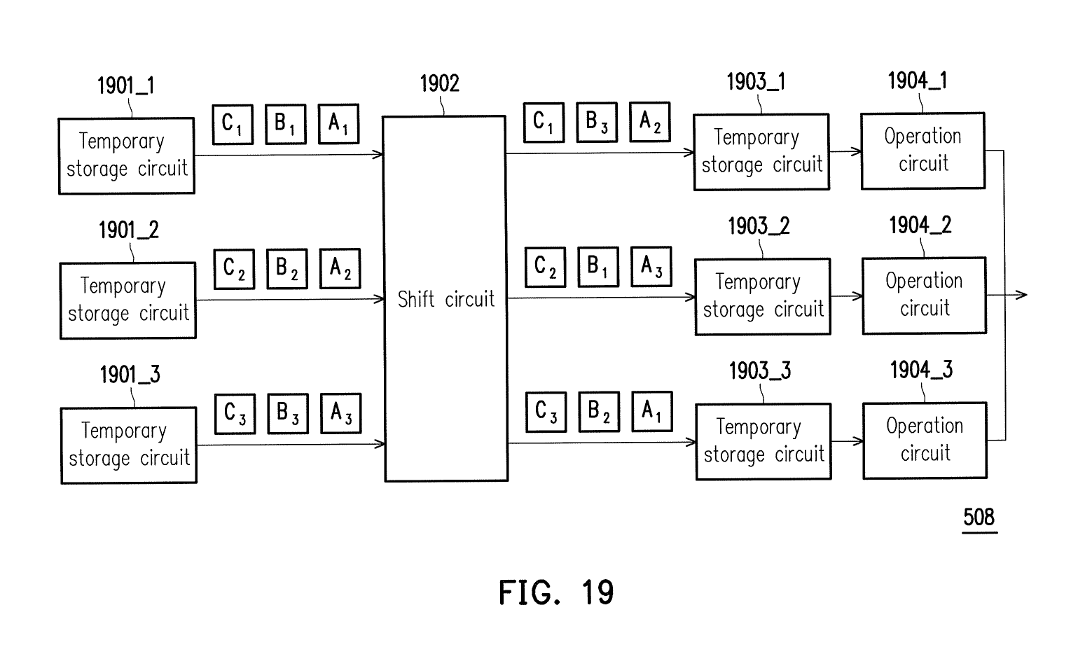

FIG. 19 is a schematic block diagram illustrating the error checking and correcting circuit according to an exemplary embodiment of the disclosure.

Referring to FIG. 19, in the present exemplary embodiment, the error checking and correcting circuit 508 at least includes temporary storage circuits 1901_1 to 1901_3, a shift circuit 1902, temporary storage circuits 1903_1 to 1903_3 and operation circuits 1904_1 to 1904_3. The temporary storage circuit 1901_1 to 1901_3 are configured to temporarily store groups in a data set that a group shifting operation is to be performed on. The shift circuit 1902 is coupled to the temporary storage circuits 1901_1 to 1901_3 and configured to perform the group shifting. The temporary storage circuit 1903_1 to 1903_3 are coupled to the shift circuit 1902 and temporarily store the shifted groups. The operation circuits 1904_1 to 1904_3 are coupled to the temporary storage circuits 1903_1 to 1903_3 and configured to perform a default logic operation to generate decoding reference data. Each circuit block illustrated in FIG. 19 will be described with reference to the exemplary embodiment illustrated in FIG. 9 below.

In a group shifting operation corresponding to a first layer of a parity check matrix, bit data (e.g., bits “A₁”, “A₂”, “A₃”) of a specific group (also referred to as a target group) among a plurality of default groups in the data set is first temporarily stored in the temporary storage circuits 1901_1 to 1901_3 and output to the shift circuit 1902. The shift circuit 1902 performs a corresponding group shifting operation on the received bit data (e.g., the bits “A₁”, “A₂”, “A₃”) and outputs a shift group (also referred to an shifted target group) (e.g., bits “A₂”, “A₃”, “A₁”) obtained through the group shifting operation to the temporary storage circuit 1903_1 to 1903_3. The bit data (e.g., the bits “A₂”, “A₃”, “A₁”) in the shifted target groups temporarily stored in the temporary storage circuit 1903_1 to 1903_3 is output to the operation circuits 1904_1 to 1904_3. In the same way, in the group shifting operation corresponding to the first layer, each bit data in the data set is sequentially output with each target group as a unit to the shift circuit 1902 for the group shifting and sequentially output with an shifted target group as a unit to the operation circuits 1904_1 to 1904_3 for the default logic operation. For example, the operation circuit 1904_1 executes the modulo-2 addition on the received bits A₂, B₃ and C₁ to obtain a syndrome S₁ in a syndrome set, the operation circuit 1904_2 executes the modulo-2 addition on the received bits A₃, B₁ and C₂ to obtain a syndrome S₂ of the syndrome set, and the operation circuit 1904_3 executes the modulo-2 addition on the received bits A₁, B₂ and C₃ to obtain a syndrome S₃ in the syndrome set. Subsequently, a group shifting operation corresponding to a second layer of the parity check matrix and the modulo-2 addition executed on the shifted groups may be achieved according to the circuit structure illustrated in FIG. 19 and thus, will not be repeated.

In different exemplary embodiments, corresponding to different stages in the iterative decoding process and/or corresponding to the data sets used for different algorithms, the circuit structure illustrated in FIG. 19 may also achieve the corresponding group shifting operations and perform the corresponding logic operations to generate the decoding reference data.

In another exemplary embodiment of FIG. 19, the temporary storage circuits 1901_1 to 1901_3 may also be combined into a temporary storage circuit, the temporary storage circuits 1903_1 to 1903_3 may also be combined into a temporary storage circuit, and the operation circuit 1904_1 to 1904_3 may also be combined into an operation circuit. Moreover, the error checking and correcting circuit 508 illustrated in FIG. 19 is merely an example, and in another exemplary embodiment of FIG. 19, the error checking and correcting circuit 508 may also include other operational circuit elements.

To summarize, in an exemplary embodiment of the disclosure, the offset threshold value and its corresponding parity check matrix are determined. Thereafter, in the iterative decoding process, the group shifting operation are performed on the groups of a data set corresponding to the parity check matrix, and the corresponding offsets are constrained as not over the set offset threshold value. Thereby, in an exemplary embodiment of the disclosure, the number of the selectors/shift registers that have to be configured in the error checking and correcting circuit can be reduced. Moreover, in an exemplary embodiment of the disclosure, generating the decoding reference data according to the shift groups can also contribute to improving the efficiency of performing some stages in the iterative decoding process. The previously described exemplary embodiments of the disclosure have the advantages aforementioned, wherein the advantages aforementioned not required in all versions of the disclosure.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A decoding method for a rewritable non-volatile memory module, comprising:
determining an offset threshold value and a check matrix corresponding to the offset threshold value, wherein the check matrix comprises at least one sub-matrix group, each sub-matrix of the at least one sub-matrix group has a default dimension, the offset threshold value is less than a default dimension value corresponding to the default dimension, and the at least one sub-matrix group comprises a first sub-matrix group;
transmitting a read command sequence, wherein the read command sequence instructs to read a physical unit of the rewritable non-volatile memory module;
receiving response data corresponding to the read command sequence; and
performing an iterative decoding process on the response data,
wherein the iterative decoding process comprises:
generating a data set corresponding to the response data, wherein the data set comprises a plurality of default groups;
shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and
generating a decoding reference data according to the first shift groups.

2. The decoding method according to claim 1, wherein the at least one sub-matrix group further comprises a second sub-matrix group,
wherein the iterative decoding process further comprises:
shifting the first shift groups according to a plurality of sub-matrices belonging to the second sub-matrix group to obtain a plurality of second shift groups, wherein an offset of each shift group in the second shift groups with respect to a corresponding group among the first shift groups is not over the offset threshold value; and
generating the decoding reference data according to the second shift groups.

3. The decoding method according to claim 1, wherein the decoding reference data is a syndrome set of a parity check procedure corresponding to a low density parity code (LDPC) algorithm.

4. The decoding method according to claim 1, wherein the decoding reference data is a syndrome weight set corresponding to a bit-flipping algorithm.

5. The decoding method according to claim 1, wherein the decoding reference data is a minimum value set of a min-sum algorithm corresponding to an LDPC algorithm.

6. The decoding method according to claim 1, wherein the offset threshold value is negatively correlated to a column weight of the check matrix,
wherein the column weight is corresponding to a total number of an element of 1 contained in a column of the check matrix.

7. The decoding method according to claim 6, wherein the offset threshold value is equal to or greater than a minimum threshold value obtained by dividing the default dimension value by the column weight.

8. A memory storage device, comprising:
a connection interface unit configured to couple to a host system;
a rewritable non-volatile memory module; and
a memory control circuit unit coupled to the connection interface unit and the rewritable non-volatile memory module,
wherein the memory control circuit unit is configured to determine an offset threshold value and a check matrix corresponding to the offset threshold value, wherein the check matrix comprises at least one sub-matrix group, each sub-matrix of the at least one sub-matrix group has a default dimension, the offset threshold value is less than a default dimension value corresponding to the default dimension, and the at least one sub-matrix group comprises a first sub-matrix group,
wherein the memory control circuit unit is further configured to transmit a read command sequence, wherein the read command sequence instructs to read a physical unit of the rewritable non-volatile memory module,
wherein the memory control circuit unit is further configured to receive response data corresponding to the read command sequence,
wherein the memory control circuit unit is further configured to perform an iterative decoding process on the response data, wherein the iterative decoding process comprises:
generating a data set corresponding to the response data, wherein the data set comprises a plurality of default groups;
shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and
generating a decoding reference data according to the first shift groups.

9. The memory storage device according to claim 8, wherein the at least one sub-matrix group further comprises a second sub-matrix group,
wherein the iterative decoding process further comprises:
shifting the first shift groups according to a plurality of sub-matrices belonging to the second sub-matrix group to obtain a plurality of second shift groups, wherein an offset of each shift group in the second shift groups with respect to a corresponding group among the first shift groups is not over the offset threshold value; and
generating the decoding reference data according to the second shift groups.

10. The memory storage device according to claim 8, wherein the decoding reference data is a syndrome set of a parity check procedure corresponding to an LDPC algorithm.

11. The memory storage device according to claim 8, wherein the decoding reference data is a syndrome weight set corresponding to a bit-flipping algorithm.

12. The memory storage device according to claim 8, wherein the decoding reference data is a minimum value set of a min-sum algorithm corresponding to an LDPC algorithm.

13. The memory storage device according to claim 8, wherein the offset threshold value is negatively correlated to a column weight of the check matrix,
wherein the column weight is corresponding to a total number of an element of 1 contained in a column of the check matrix.

14. The memory storage device according to claim 13, wherein the offset threshold value is equal to or greater than a minimum threshold value obtained by dividing the default dimension value by the column weight.

15. A memory control circuit unit configured to control a rewritable non-volatile memory module, the memory control circuit unit comprising:
a host interface configured to couple to a host system;
a memory interface configured to couple to the rewritable non-volatile memory module;
an error checking and correcting circuit; and
a memory management circuit coupled to the host interface, the memory interface and the error checking and correcting circuit,
wherein the memory management circuit is configured to determine an offset threshold value and a check matrix corresponding to the offset threshold value, wherein the check matrix comprises at least one sub-matrix group, each sub-matrix of the at least one sub-matrix group has a default dimension, the offset threshold value is less than a default dimension value corresponding to the default dimension, and the at least one sub-matrix group comprises a first sub-matrix group,
wherein the memory management circuit is further configured to transmit a read command sequence, wherein the read command sequence instructs to read a physical unit of the rewritable non-volatile memory module,
wherein the memory management circuit is further configured to receive response data corresponding to the read command sequence,
wherein the error checking and correcting circuit is configured to perform an iterative decoding process on the response data, wherein the iterative decoding process comprises:
generating a data set corresponding to the response data, wherein the data set comprises a plurality of default groups;
shifting the default groups according to a plurality of sub-matrices belonging to the first sub-matrix group to obtain a plurality of first shift groups, wherein an offset of each shift group in the first shift groups with respect to a corresponding group among the default groups is not over the offset threshold value; and
generating a decoding reference data according to the first shift groups.

16. The memory control circuit unit according to claim 15, wherein the at least one sub-matrix group further comprises a second sub-matrix group,
wherein the iterative decoding process further comprises:
shifting the first shift groups according to a plurality of sub-matrices belonging to the second sub-matrix group to obtain a plurality of second shift groups, wherein an offset of each shift group in the second shift groups with respect to a corresponding group among the first shift groups is not over the offset threshold value; and
generating the decoding reference data according to the second shift groups.

17. The memory control circuit unit according to claim 15, wherein the decoding reference data is a syndrome set of a parity check procedure corresponding to an LDPC algorithm.

18. The memory control circuit unit according to claim 15, wherein the decoding reference data is a syndrome weight set corresponding to a bit-flipping algorithm.

19. The memory control circuit unit according to claim 15, wherein the decoding reference data is a minimum value set of a min-sum algorithm corresponding to an LDPC algorithm.

20. The memory control circuit unit according to claim 15, wherein the offset threshold value is negatively correlated to a column weight of the check matrix,
wherein the column weight is corresponding to a total number of an element of 1 contained in a column of the check matrix.

21. The memory control circuit unit according to claim 20, wherein the offset threshold value is equal to or greater than a minimum threshold value obtained by dividing the default dimension value by the column weight.

22. The memory control circuit unit according to claim 15, wherein the error checking and correcting circuit comprises:
at least one first temporary storage circuit configured to temporarily store a target group among the default groups;
a shift circuit coupled to at least one first temporary storage circuit and configured to shift the target group and output an shifted target group among the first shift groups corresponding to the target group;
at least one second temporary storage circuit coupled to the shift circuit and configured to temporarily store the shifted target group; and
at least one operation circuit coupled to the at least one second temporary storage circuit and configured to perform a logic operation on the shifted target group and generate the decoding reference data.
